(19) United States
(12) Patent Application Publication
(10) Pub. No.: US 2025/0343852 A1
(43) Pub. Date: Nov. 6, 2025

(54) ELECTRONIC DEVICE COMPRISING KEY ASSEMBLY

(71) Applicant: Samsung Electronics Co., Ltd., Suwon-si (KR)

(72) Inventors: Junhyuk KIM, Suwon-si (KR); Jaeuk AHN, Suwon-si (KR); Moonsun KIM, Suwon-si (KR); Jaehyoung YOU, Suwon-si (KR); Hoyoung JEONG, Suwon-si (KR); Baekeun CHO, Suwon-si (KR); Hyoungtak CHO, Suwon-si (KR); Hyunggwang KANG, Suwon-si (KR); Sukdong KIM, Suwon-si (KR); Soohyun SEO, Suwon-si (KR); Hyunju HONG, Suwon-si (KR)

(21) Appl. No.: 19/270,997

(22) Filed: Jul. 16, 2025

Related U.S. Application Data
(63) Continuation of application No. PCT/KR2023/021334, filed on Dec. 21, 2023.

(30) Foreign Application Priority Data
Jan. 16, 2023 (KR) 10-2023-0006191
Feb. 8, 2023 (KR) 10-2023-0017036

(51) Int. Cl. H04M 1/23; H03K 17/90; H04M 1/02

(52) U.S. Cl. CPC H04M 1/236; H03K 17/90; H04M 1/0237; H04M 1/0268

(57) ABSTRACT

An electronic device is provided. The electronic device includes a first housing, a second housing configured to slide relative to the first housing, a flexible display, including a first display area and a second display area extending from the first display area, and configured to move at least a portion of the second display area based on a slide movement of the second housing, and a key assembly disposed on a side of the first housing, the flexible display includes a first display area and a second display area extending from the first display area, wherein the key assembly includes a key circuit board, a first switch member disposed on a first area of the key circuit board, a second switch member disposed on a second area of the key circuit board, a function change key disposed to be slidable between the first switch member and the second switch member, a first magnet, and a second magnet.

### CROSS-REFERENCE TO RELATED APPLICATION(S)

This application is a continuation application, claiming priority under 35 U.S.C. § 365 (c), of an International application No. PCT/KR2023/021334, filed on Dec. 21, 2023, which is based on and claims the benefit of a Korean patent application number 10-2023-0006191, filed on Jan. 16, 2023, in the Korean Intellectual Property Office, and of a Korean patent application number 10-2023-0017036, filed on Feb. 8, 2023, in the Korean Intellectual Property Office, the disclosure of each of which is incorporated by reference herein in its entirety.

### BACKGROUND

### 1. Field

The disclosure relates to an electronic device including a key assembly.

### 2. Description of Related Art

The development of information and communication technology and semiconductor technology has led to the integration of various functions into a single portable electronic device. For example, electronic devices may implement not only communication functions, but also entertainment functions such as games, multimedia functions such as music/video playback, communication and security functions for mobile banking, calendar management, and electronic wallet functions. These electronic devices are being miniaturized so that they may be conveniently carried by users.

As mobile communication services are expanded to the multimedia service area, there is a need to increase the size of the display of an electronic device in order for a user to fully use multimedia services as well as voice calls and short messages. However, the size of the display of an electronic device may be in a trade-off relationship with the miniaturization of the electronic device.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide an electronic device including a key assembly.

Additional aspects will be set forth in part in the description which follows and, in part, will be apparent from the description, or may be learned by practice of the presented embodiments.

In accordance with an aspect of the disclosure, an electronic device is provided. The electronic device includes a first housing, a second housing configured to slide relative to the first housing, a flexible display including a first display area and a second display area extending from the first display area, and configured to move at least a portion of the second display area based on a slide movement of the second housing, and a key assembly disposed on a side surface of the first housing, wherein the key assembly includes a key circuit board, a first switch member disposed on a first area of the key circuit board, a second switch member disposed on a second area of the key circuit board, a function change key disposed to be slidable between the first switch member and the second switch member, a first magnet disposed on one end of the function change key to be slidable, and a second magnet disposed on the other end of the function change key to be slidable.

In accordance with another aspect of the disclosure, an electronic device is provided. The electronic device includes a first housing, a second housing configured to slide relative to the first housing, a flexible display including a first display area and a second display area extending from the first display area, and configured to move at least a portion of the second display area based on a slide movement of the second housing, and a key assembly disposed on a side surface of the first housing, wherein the key assembly includes a key circuit board, a first switch member disposed on a first area of the key circuit board, a second switch member disposed on a second area of the key circuit board, and a function change key, disposed to be slidable between the first switch member and the second switch member, wherein the function change key is configured to be slidable between a first position adjacent to the first switch member and a second position adjacent to the second switch member, and wherein the electronic device is configured to perform a set function based on an external input detected by at least one of the first switch member or the second switch member, and perform different functions when the function change key is in the first position and the second position.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating an electronic device in a network environment according to an embodiment of the disclosure;

FIG. 2 is a diagram illustrating a second display area of a display accommodated inside a housing according to an embodiment of the disclosure;

FIG. 3 is a diagram illustrating a second display area of a display exposed to the outside of a housing according to an embodiment of the disclosure;

FIG. 4 is an exploded perspective view illustrating an electronic device according to an embodiment of the disclosure;

FIG. 5A is a cross-sectional view taken along line A-A′ of FIG. 2 according to an embodiment of the disclosure;

FIG. 5B is a cross-sectional view taken along line B-B′ of FIG. 3 according to an embodiment of the disclosure;

FIG. 6 is a cross-sectional view illustrating an electronic device and a key assembly, taken along line C-C′ of FIG. 2 according to an embodiment of the disclosure;

FIG. 7 is an exploded perspective view illustrating a first cover member and a key assembly in an electronic device according to an embodiment of the disclosure;

FIG. 8 is a perspective view illustrating a key assembly in an electronic device according to an embodiment of the disclosure;

FIG. 9 is a diagram illustrating a function change key and a magnet in a key assembly according to an embodiment of the disclosure;

FIG. 10 is a plan view illustrating a key assembly, when a function change key is in a first state according to an embodiment of the disclosure;

FIG. 11 is a plan view illustrating a key assembly, when a function change key is in a second state according to an embodiment of the disclosure;

FIG. 12 is a perspective view illustrating a first cover member and a key circuit board of a key assembly in an electronic device according to an embodiment of the disclosure;

FIG. 13 is a plan view illustrating a first cover member and some components of a key assembly in an electronic device according to an embodiment of the disclosure;

FIG. 14 is a perspective view illustrating a first cover member and some components of a key assembly in an electronic device according to an embodiment of the disclosure;

FIG. 15 is graphs of first Hall sensor values and second Hall sensor values according to positions of a function change key in a key assembly according to an embodiment of the disclosure;

FIG. 16A is a perspective view illustrating an operation of a key assembly in the presence of an external magnet around an electronic device according to an embodiment of the disclosure;

FIG. 16B is a perspective view illustrating an operation of a key assembly in the presence of an external magnet around an electronic device according to an embodiment of the disclosure;

FIG. 16C is a perspective view illustrating an operation of a key assembly in the presence of an external magnet around an electronic device according to an embodiment of the disclosure;

FIG. 17A is graphs of first Hall sensor values and second Hall sensor values according to positions of the function change key in the key assembly of FIG. 16A according to an embodiment of the disclosure;

FIG. 17B is graphs of first Hall sensor values and second Hall sensor values according to positions of the function change key in the key assembly of FIG. 16B according to an embodiment of the disclosure;

FIG. 17C is graphs of first Hall sensor values and second Hall sensor values according to positions of the function change key in the key assembly of FIG. 16C according to an embodiment of the disclosure;

FIG. 18A is graphs of first Hall sensor values and second Hall sensor values according to positions of the function change key in the key assembly of FIG. 16A according to an embodiment of the disclosure;

FIG. 18B is graphs of first Hall sensor values and second Hall sensor values according to positions of the function change key in the key assembly of FIG. 16B according to an embodiment of the disclosure;

FIG. 18C is graphs of first Hall sensor values and second Hall sensor values according to positions of the function change key in the key assembly of FIG. 16C according to an embodiment of the disclosure; and

FIG. 19 is a conceptual diagram illustrating an operation of extending or reducing a display using a key assembly in an electronic device according to an embodiment of the disclosure.

Throughout the drawings, like reference numerals will be understood to refer to like parts, components, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

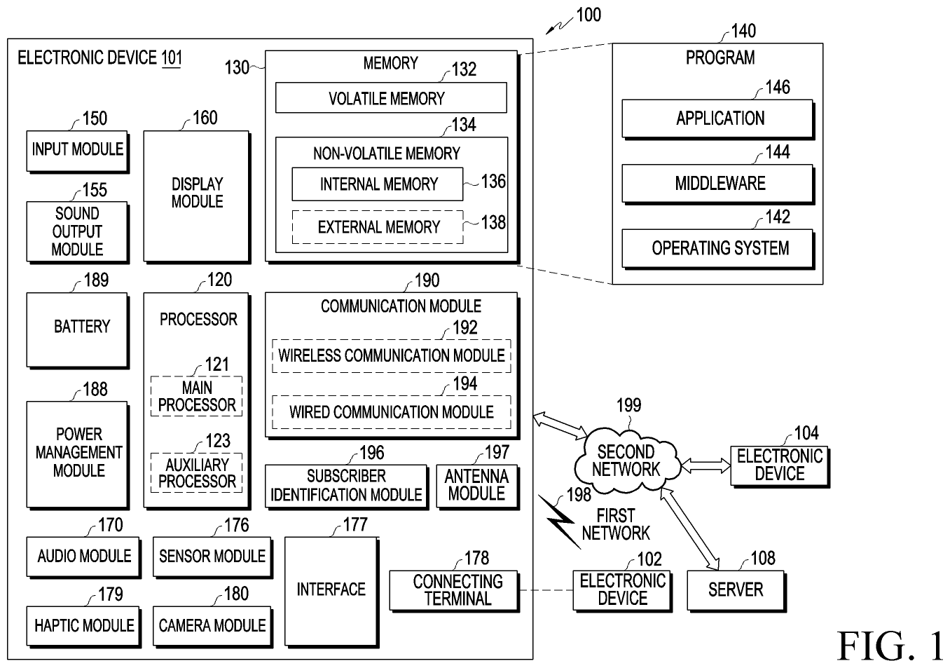

FIG. 1 is a block diagram illustrating an electronic device 101 in a network environment 100 according to an embodiment of the disclosure.

Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one of the components (e.g., the connecting terminal 178) may be omitted from the electronic device 101, or one or more other components may be added in the electronic device 101. In an embodiment, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the strength of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™ wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to an embodiment, the antenna module 197 may form an mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

In the following detailed description, a longitudinal direction, width direction, and/or thickness direction of an electronic device may be mentioned. The longitudinal direction may be defined as a ‘Y-axis direction’, the width direction as an ‘X-axis direction’, and/or the thickness direction as a ‘Z-axis direction’. In an embodiment, regarding a direction in which a component is directed, ‘negative/positive (−/+)’ may be mentioned together with the Cartesian coordinate system illustrated in the drawings. For example, a front surface of an electronic device or housing may be defined as a ‘surface facing a +Z direction’, and a rear surface thereof as a ‘surface facing a −Z direction’. In an embodiment, a side surface of the electronic device or housing may include an area facing a +Z direction, an area facing a +Y direction, an area facing a −X direction, and/or an area facing a −Y direction. Further, in an embodiment, the ‘X-axis direction’ may include both the ‘−X direction’ and the ‘+X direction’. This is based on the Cartesian coordinate system illustrated in the drawings, for simplicity of description, and it should be noted that the description of these directions or components does not limit an embodiment of the disclosure. For example, the direction in which the afore-mentioned front surface or rear surface faces may be changed depending on whether the electronic device is in an unfolded or folded state, and the afore-mentioned directions may be interpreted differently depending on a user's gripping habit.

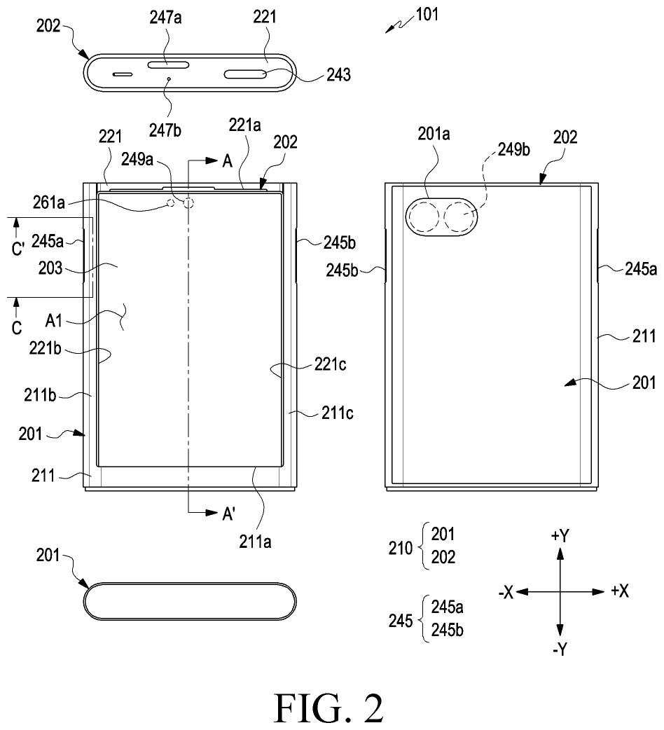

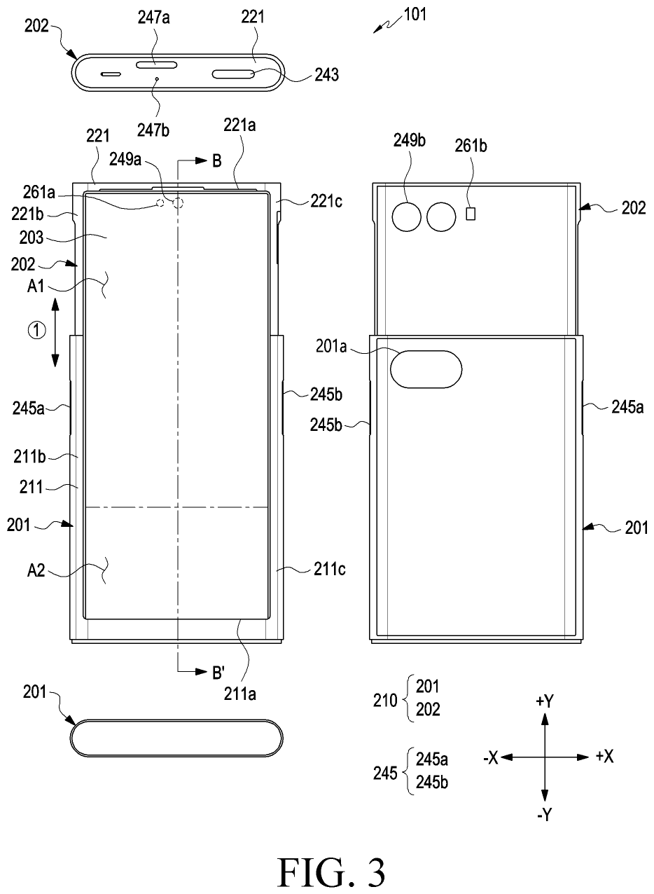

FIG. 2 is a diagram illustrating a state in which a second display area of a display is accommodated in a housing according to an embodiment of the disclosure. FIG. 3 is a diagram illustrating a state in which the second display area of the display is exposed to the outside of the housing according to an embodiment of the disclosure.

FIGS. 2 and 3 illustrate a structure in which a display 203 (e.g., a flexible display or rollable display) extends in a longitudinal direction (e.g., +Y direction), when viewed from the front of the electronic device 101. However, the direction of extension of the display 203 is not limited to one direction (e.g., +Y direction). For example, a design modification may be made such that the display 203 is extendable in an upward direction (e.g., +Y direction), a right direction (e.g., +X direction), a left direction (e.g., −X direction), and/or a downward direction (e.g., −Y direction).

The state illustrated in FIG. 2 may be defined as a slide-in state of the electronic device 101 or a closed state of the second display area A2 of the display 203.

The state illustrated in FIG. 3 may be defined as a slide-out state of the electronic device 101 or an opened state of the second display area A2 of the display 203. Referring to FIGS. 2 and 3, the electronic device 101 may include a housing 210. The housing 210 may include a first housing 201 and a second housing 202 disposed to be movable with respect to the first housing 201. In an embodiment, it may be interpreted as a structure in which the first housing 201 is disposed to be slidable with respect to the second housing 202 in the electronic device 101. According to an embodiment, the second housing 202 may be disposed to be reciprocal with respect to the first housing by a predetermined distance in a direction illustrated with respect to the first housing 201, for example, in a direction indicated by an arrow \textcircled{1}.

According to an embodiment, the second housing 202 may be referred to as a slide part or a slide housing, and movable with respect to the first housing 201. According to an embodiment, the second housing 202 may accommodate various electrical and electronic components such as a circuit board or a battery.

According to an embodiment, the slide-in state of the electronic device 101 (or the slide-out state of the electronic device 101) may be changed to the slide-out state of the electronic device 101 (or the slide-in state of the electronic device 101) based on a predefined user input. For example, the slide-in state of the electronic device 101 (or the slide-out state of the electronic device 101) may be changed to the slide-out state (or the slide-in state of the electronic device 101) in response to a user input to a physical button exposed through a portion of the first housing 201 or a portion of the second housing 202. For example, the slide-in state (or the slide-out state of the electronic device 101) may be changed to the slide-out state (or the slide-in state of the electronic device 101) in response to a touch input to an executable object displayed in a screen display area (e.g., a first display area A1). For example, the slide-in state (or the slide-out state of the electronic device 101) may be changed to the slide-out state (or the slide-in state of the electronic device 101) in response to a touch input having a contact point on the screen display area (e.g., the first display area A1) and having a strength equal to or greater than a reference level. For example, the slide-in state (or the slide-out state of the electronic device 101) may be changed to the slide-out state (or the slide-in state of the electronic device 101) in response to a voice input received through a microphone. For example, the slide-in state (or the slide-out state of the electronic device 101) may be changed to the slide-out state (or the slide-in state of the electronic device 101) in response to an external force applied to the first housing 201 and/or the second housing 202 to move the second housing 202 with respect to the first housing 201. For example, the slide-in state (or the slide-out state of the electronic device 101) may be changed to the slide-out state (or the slide-in state of the electronic device 101) in response to a user input identified from an external electronic device (e.g., earbuds or a smart watch) connected to the electronic device 101. However, the slide-in/slide-out operation of the electronic device 101 is not limited thereto.

According to an embodiment, the first housing 201 may accommodate a motor, a speaker, a SIM socket, and/or a sub-circuit board electrically connected to a main circuit. The second housing 202 may accommodate the main circuit board with electrical components such as an application processor (AP) and a communication processor (CP) mounted thereon.

According to an embodiment, the first housing may include a first cover member 211 (e.g., a main case). The first cover member 211 may include a (1-1)^{th} sidewall 211a, a (1-2)^{th} sidewall 211b extending from the (1-1)^{th} sidewall 211a, and a (1-3)^{th} sidewall 211c extending from the (1-1)^{th} sidewall 211a and substantially parallel to the (1-2)^{th} sidewall 211b. According to an embodiment, the (1-2)^{th} sidewall 211b and the (1-3)^{th} sidewall 211c may be formed substantially perpendicular to the (1-1)^{th} sidewall 211a.

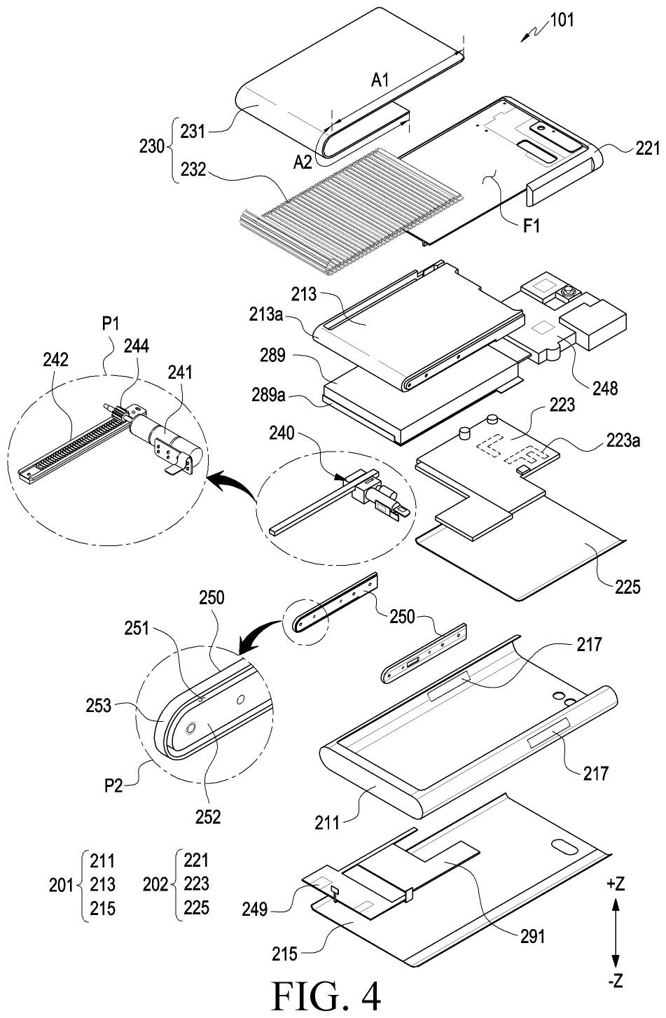

According to an embodiment, the (1-1)^{th} sidewall 211a, the (1-2)^{th} sidewall 211b, and the (1-3)^{th} sidewall 211c of the first cover member 211 may be formed with one side (e.g., a front surface) open to accommodate (or surround) at least a portion of the second housing 202. For example, the second housing 202 may be at least partially surrounded by the first housing 201 and slide in a direction parallel to a first surface (e.g., a first surface F1 in FIG. 4), for example, in the direction of the arrow \textcircled{1}, while being guided by the first housing 201. According to an embodiment, the (1-1)^{th} sidewall 211a, the (1-2)^{th} sidewall 211b, and/or the (1-3)^{th} sidewall 211c of the first cover member 211 may be integrally formed. According to an embodiment, the (1-1)^{th} sidewall 211a, the (1-2)^{th} sidewall 211b, and/or the (1-3)^{th} sidewall 211c of the first cover member 211 may be formed as separate housings and coupled or assembled.

According to an embodiment, the first cover member 211 may be formed to surround at least a portion of the display 203. For example, at least a portion of the display 203 may be formed to be surrounded by the (1-1)^{th} sidewall 211a, the (1-2)^{th} sidewall 211b, and/or the (1-3)^{th} sidewall 211c of the first cover member 211.

According to an embodiment, the second housing 202 may include a second cover member 221 (e.g., a slide plate). The second cover member 221 may have a plate shape and include the first surface (e.g., the first surface F1 in FIG. 4) supporting internal components. For example, the second cover member 221 may support at least a portion (e.g., the first display area A1) of the display 203. According to an embodiment, the second cover member 221 may be referred to as a front cover.

According to an embodiment, the second cover member 221 may include a (2-1)^{th} sidewall 221a, a (2-2)^{th} sidewall 221b extending from the (2-1)^{th} sidewall 221a, and a (2-3)^{th} sidewall 221c extending from the (2-1)^{th} sidewall 221a and substantially parallel to the (2-2)^{th} sidewall 221b. According to an embodiment, the (2-2)^{th} sidewall 221b and the (2-3)^{th} sidewall 221c may be formed substantially perpendicular to the (2-1)^{th} sidewall 221a.

According to various embodiments, the second housing 202 may move in a first direction (e.g., the direction of the arrow \textcircled{1}) parallel to the (2-2)^{th} sidewall 211b or the (2-3)^{th} sidewall 211c, forming the slide-in state and slide-out state of the electronic device 101. The second housing 202 may move to be located at a first distance from the (1-1)^{th} sidewall 211a of the first hosing 201 in the slid-in state of the electronic device 101 and at a second distance larger than the first distance from the (1-1)^{th} sidewall 211a of the first hosing 201 in the slide-out state of the electronic device 101. In an embodiment, the first housing 201 may be formed to surround a portion of the (2-2)^{th} sidewall 221b and a portion of the (2-3)^{th} sidewall 221c in the slide-in state of the electronic device 101.

According to an embodiment, the electronic device 101 may have an intermediate state between the slide-in state (e.g., a fully closed state in FIG. 2) and the slide-out state (e.g., a fully opened state in FIG. 3). The distance between the (1-1)^{th} sidewall 211a and the (2-1)^{th} sidewall 221a in the intermediate state of the electronic device 101 may be smaller than the distance between the (1-1)^{th} sidewall 211a and the (2-1)^{th} sidewall 221a in the fully opened state of the electronic device 101, and greater than the distance between the (1-1)^{th} sidewall 211a and the (2-1)^{th} sidewall 221a in the fully closed state of the electronic device 101. According to an embodiment, as at least a portion of the display 203 slides in the intermediate state of the electronic device 101, an area exposed to the outside may vary. For example, in the intermediate state of the electronic device 101, the ratio between the width (an X-direction length) and height (a Y-direction length) of the display 203 and/or the distance between the (1-1)^{th} sidewall 211a and the (2-1)^{th} sidewall 221a may be changed based on sliding movement of the electronic device 101.

According to an embodiment, the electronic device 101 may include the display 203, key input devices 245a and 245b, a connector hole 243, audio modules 247a and 247b, or camera modules 249a and 249b. According to an embodiment, the electronic device 101 may further include an indicator (e.g., a light emitting diode (LED) device) or various sensor modules.

According to various embodiments, the display 203 may include the first display area A1 and the second display area A2 configured to be exposed to the outside of the electronic device 101 based on sliding movement of the housing 210. According to an embodiment, the first display area A1 may be disposed on the second housing 202. For example, the first display area A1 may be disposed on the second cover member 221 of the second housing 202. According to an embodiment, the second display area A2 may extend from the first display area A1, and as the first housing 201 slides with respect to the second housing 202, the second display area A2 may be accommodated into the first housing 201 or visually exposed to the outside of the electronic device 101. According to an embodiment, as the electronic device 101 is changed from the slide-out state to the slide-in state, the display 203 may extend in a downward direction (e.g., −Y direction). For example, in the slide-out state of the electronic device 101, the second display area A2 may be visually exposed under the display 203 (e.g., in the −Y direction). According to an embodiment, as the electronic device 101 is changed from the slide-in state to the slide-out state, the display 203 may extend in an upward direction (e.g., +Y direction). For example, in the slide-out state of the electronic device 101, the second display area A2 may be visually exposed on the display 203 (e.g., in the +Y direction).

According to an embodiment, the second display area A2 may be accommodated into an internal space of the housing 210 or exposed to the outside of the electronic device 101 by moving while being guided substantially by an area (e.g., a curved surface 213a of FIG. 4) of the first housing. According to an embodiment, the second display area A2 may move based on the sliding movement of the second housing 202 in the first direction (e.g., the direction indicated by the arrow \textcircled{1}). For example, a portion of the second display area A2 may be deformed into a curved surface at a position corresponding to the curved surface 213a of the first housing 201 during the sliding movement of the second housing 202.

According to an embodiment, when viewed from above the second cover member 221 (e.g., a front cover), when the electronic device 101 is changed from the slide-in state to the slide-out state (e.g., the second housing 202 slides to extend from the first housing 201), the second display area A2 may form a substantially flat surface with the first display area A1, while gradually being exposed to the outside of the first housing 201. According to an embodiment, the display 203 may be coupled to or disposed adjacent to a touch sensing circuit, a pressure sensor capable of measuring the intensity (pressure) of a touch, and/or a digitizer that detects a magnetic stylus pen. According to an embodiment, regardless of the slide-in or slide-out state of the electronic device 101, an exposed portion of the second display area A2 may be located on a portion (e.g., the curved surface 213a of FIG. 4) of the first housing, and a portion of the second display area A2 may maintain a curved shape at the position corresponding to the curved surface 213a.

According to an embodiment, the key input devices 245a and 245b may be located in an area of the housing 210 (e.g., the first housing 201 and/or the second housing 202). According to an embodiment, at least some of the key input devices 245a and 245b may be disposed on the (1-1)^{th} sidewall 211a, the (1-2)^{th} sidewall 211b, and/or the (1-3)^{th} sidewall 211c of the first housing 201. In an embodiment, the key input devices 245a and 245b may include a first key assembly 245a disposed on the (1-2)^{th} sidewall 211b of the first housing 201 and a second key assembly 245b disposed on the (1-3)^{th} sidewall 211c of the first housing 201. For example, the first key assembly 245a and/or the second key assembly 245b may be disposed in a through hole or recess formed in the (1-2)^{th} sidewall 211b and/or the (1-3)^{th} sidewall 211c of the first housing 201. For example, the first key assembly 245a and/or the second key assembly 245b may be connected to the first housing 201 through a connecting member for preventing separation from the first housing 201, and the connecting member may be disposed in the through hole or recess of the first housing 201. For example, each of the first key assembly 245a and/or the second key assembly 245b may include a pair of volume control keys and a power key. For example, different functions may be assigned to the first key assembly 245a and/or the second key assembly 245b depending on a user's settings, and for example, a function for immediately activating a voice assistant function or a camera function may be assigned.

However, the numbers of keys, positions, and/or functions of the key input devices 245a and 245b are not limited to those described above. Depending on the appearance and a use state, the electronic device 101 may be designed to be without the illustrated key input devices 245a and 245b or to include additional key input device(s). According to an embodiment, the electronic device 101 may include a key input device not shown, such as a home key button or a touch pad disposed around the home key button. For example, at least some of the key input devices 245a and 245b may be disposed on the (2-1)^{th} sidewall 221a, the (2-2)^{th} sidewall 221b, and/or the (2-3)^{th} sidewall 221c of the second housing 202.

According to an embodiment, the connector hole 243 may be omitted depending on an embodiment, and may accommodate a connector (e.g., a USB connector) for transmitting power and/or data to and from an external electronic device. According to an embodiment (not shown), the electronic device 101 may include a plurality of connector holes 243, and some of the plurality of connector holes 243 may function as connector holes for transmitting and receiving audio signals to and from an external electronic device. In the illustrated embodiment, the connector hole 243 is disposed on the second housing 202, to which the disclosure is not limited. The connector hole 243 or a connector hole not shown may be disposed on the first housing 201.

According to an embodiment, the audio modules 247a and 247b may include at least one speaker hole 247a or at least one microphone hole 247b. One of the speaker holes 247a may be provided as a receiver hole for voice calls, and the other may be provided as an external speaker hole. The electronic device 101 may include a microphone for obtaining sound, and the microphone may obtain sound external to the electronic device 101 through the microphone hole 247b. According to an embodiment, the electronic device 101 may include a plurality of microphones to detect the direction of sound. According to an embodiment, the electronic device 101 may include an audio module in which the speaker hole 247a and the microphone hole 247b are implemented as a single hole, or include a speaker (e.g., a piezo speaker) without the speaker hole 247a. According to an embodiment, the speaker hole 247a and the microphone hole 247b may be located in the first housing 201 and/or the second housing 202.

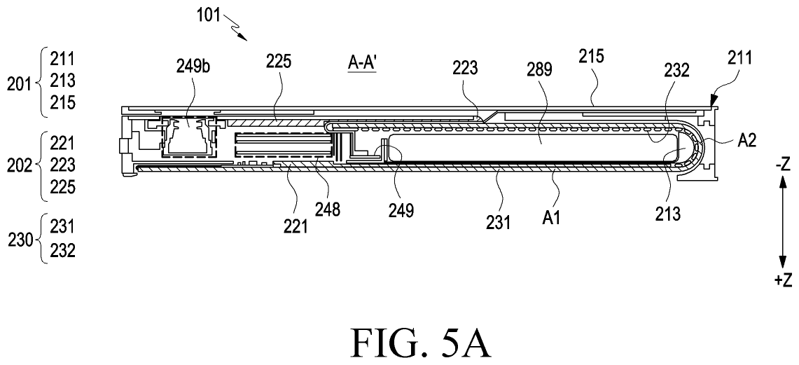

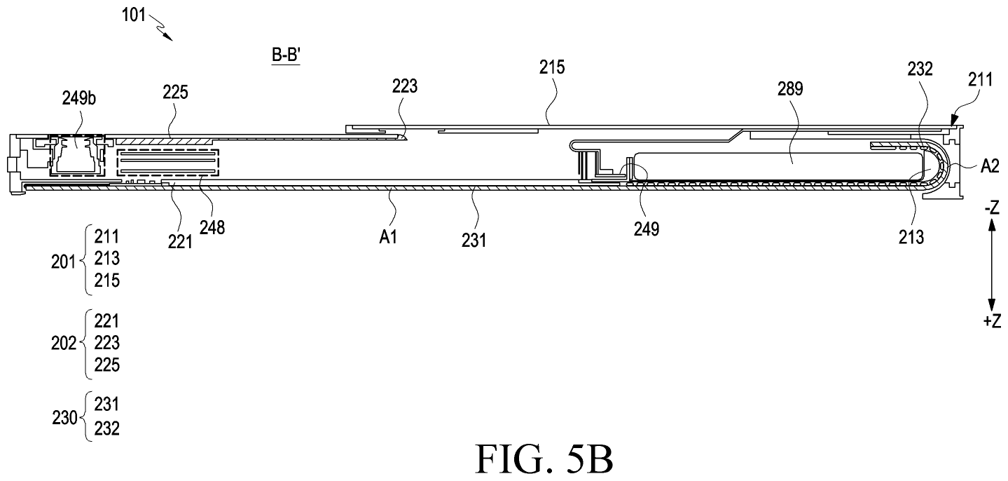

According to an embodiment, the camera modules 249a and 249b may include a first camera module 249a (e.g., front camera) and a second camera module 249b (e.g., rear camera) (e.g., the second camera module 249b in FIGS. 5A and 5B). According to an embodiment, the electronic device 101 may include at least one of a wide-angle camera, a telephoto camera, or a close-up camera, and according to an embodiment, include an IR projector and/or an IR receiver to measure a distance to a subject. The camera modules 249a and 249b may include one or more lenses, an image sensor, and/or an image signal processor. The first camera module 249a may be disposed to face in the same direction as the display 203. For example, the first camera module 249a may be disposed around the first display area A1 or in an area overlapping the display 203 and, when disposed in the area overlapping the display 203, may be able to capture a subject through the display 203. According to an embodiment, the first camera module 249a may not be visually exposed to a screen display area (e.g., the first display area A1) and include a hidden under display camera (UDC). According to an embodiment, the second camera module 249a may capture a subject in a direction opposite to the display A1. According to an embodiment, the first camera module 249a and/or the second camera module 249b may be disposed on the second housing 202. According to an embodiment, a plurality of second camera modules 249b may be formed and arranged in various manners. For example, the plurality of second camera modules 249b may be arranged along the width direction (X-axis direction) substantially perpendicular to a sliding movement direction (e.g., Y-axis direction) of the electronic device 101. In another example, the plurality of second camera modules 249b may be arranged along the sliding movement direction (e.g., Y-axis direction) of the electronic device 101. In another example, the plurality of second camera modules 249b may be arranged in N*M rows and columns like a matrix.

According to an embodiment, the second camera module 249b may not be visually exposed to the outside of the electronic device 101 in the slide-in state of the electronic device 101, and may capture the outside of the electronic device 101 in the slide-out state of the electronic device 101. According to an embodiment, the second camera module 249b may capture the outside of the electronic device 101 in the slide-in state and/or slide-out state of the electronic device 101. For example, at least a portion (e.g., a first rear plate 215 and/or a second rear plate 225 in FIG. 4) of the housing 210 may be substantially transparent, and the second camera module 249b may capture the outside of the electronic device 101 through the first rear plate 215 and/or the second rear plate 225. According to an embodiment, in the slide-in state and slide-out state of the electronic device 101, the second camera module 249b may be visually exposed to the outside of the electronic device 101 and capture the outside. For example, the first housing 201 (e.g., the first rear plate 215 in FIG. 4) may include an opening 201a for the second camera module 249b.

According to an embodiment, an indicator (not shown) of the electronic device 101 may be disposed in the first housing 201 or the second housing 202, and include an LED to provide state information about the electronic device 101 as a visual signal. Sensor modules 261a and 261b of the electronic device 101 may generate an electrical signal or data value corresponding to an internal operational state or an external environmental state of the electronic device 101. The sensor modules 261a and 261b may include a proximity sensor, a fingerprint sensor, and/or a biometric sensor (e.g., an iris/facial recognition sensor or an HRM sensor). In another embodiment, the sensor modules 261a and 261b may further include at least one of a gesture sensor, a gyro sensor, a barometric pressure sensor, a magnetic sensor, an acceleration sensor, a grip sensor, a color sensor, an IR sensor, a temperature sensor, a humidity sensor, or an illuminance sensor. According to an embodiment, the sensor modules 261a and 261b may be disposed in the first housing 201 and/or the second housing 202. For example, the sensor modules 261a and 261b may include a first Hall sensor module 261a (e.g., a proximity sensor or an illuminance sensor) disposed on the front surface of the electronic device 101 and/or a second sensor module 261b (e.g., a heart rate monitoring (HRM) sensor) disposed on the rear surface of the electronic device 101.

FIG. 4 is an exploded perspective view illustrating an electronic device according to an embodiment of the disclosure. FIG. 5A is a cross-sectional view taken along line A-A′ of FIG. 2 according to an embodiment of the disclosure. FIG. 5B is a cross-sectional view taken along line B-B′ of FIG. 3 according to an embodiment of the disclosure.

Referring to FIGS. 4, 5A, and/or 5B, the electronic device 101 may include the first housing 201, the second housing 202, a display assembly 230, and a driving structure 240. The configurations of the first housing 201, the second housing 202, and the display assembly 230 in FIGS. 4, 5A, and/or 5B may be wholly or partially identical to those of the first housing 201, the second housing 202, and the display 231 in FIGS. 2 and/or 3. The embodiment of FIGS. 2 and/or 3 may be partially combined with the embodiment of FIGS. 4, 5A, and/or 5B.

According to an embodiment, the first housing 201 may include the first cover member 211 (e.g., the first cover member 211 in FIGS. 2 and 3), the frame 213, and the first rear plate 215.

According to an embodiment, the first cover member 211 may accommodate at least a portion of the frame 213 and a component (e.g., a battery 289) located on the frame 213. According to an embodiment, the first cover member 211 may be formed to surround at least a portion of the second housing 202. According to an embodiment, the first cover member 211 may protect components (e.g., a second circuit board 249 and the frame 213) located in the first housing from external impact. According to an embodiment, the second circuit board 249 accommodating electronic components (e.g., the processor 120 and/or the memory 130 of FIG. 1) may be connected to the first cover member 211. According to one embodiment, the first cover member 211 may include at least one accommodation hole 217 in which at least one key input device (e.g., the key input devices 245a and 245b of FIGS. 2 and 3) is disposed. For example, the first cover member 211 may include a plurality of (e.g., two) accommodation holes 217 formed in portions of sidewalls (e.g., the (1-2)^{th} sidewall 211b and the (1-3)^{th} sidewall 211b). For example, the accommodation holes 217 may be formed in a shape corresponding to at least portions of the first key assembly 249a and the second key assembly 249b.

According to an embodiment, the frame 213 may be connected to the first cover member 211. For example, the frame 213 may be connected to the first cover member 211, and the second housing 202 may move relative to the first cover member 211 and/or the frame 213. According to an embodiment, the frame 213 may accommodate the battery 289. For example, the frame 213 may include a groove for accommodating the battery 289 therein. The frame 213 may be connected to a battery cover 289a and surround at least a portion of the battery 289, together with the battery cover 289a. According to an embodiment, the frame 213 may include the curved surface 213a facing the display assembly 230.

According to an embodiment, the first rear plate 215 may substantially form at least a portion of the exterior of the first housing 201 or the electronic device 101. For example, the first rear plate 215 may be coupled to an outer surface of the first cover member 211. According to an embodiment, the first rear plate 215 may provide a decorative effect on the exterior of the electronic device 101. The first rear plate 215 may be manufactured using at least one of metal, glass, synthetic resin, or ceramic.

According to an embodiment, the second housing 202 may include the second cover member 221 (e.g., the second cover member 221 in FIGS. 2 and 3), a rear cover 223, and a second rear plate 225.

According to an embodiment, the second cover member 221 may be connected to the first housing 201 through a guide rail 250 and reciprocate in a straight line in one direction (e.g., the direction of the arrow \textcircled{1} in FIGS. 2 and 3) while being guided by the guide rail 250.

According to embodiments, the second cover member 221 may support at least a portion of the display 203. For example, the second cover member 221 may include the first surface F1, and the first display area A1 of the display 203 may be substantially located on the first surface F1 and maintained in a flat shape. According to an embodiment, the second cover member 221 may be formed of a metallic material and/or a non-metallic (e.g., polymer) material. According to an embodiment, a first circuit board 248 accommodating electronic components (e.g., the processor 120 and/or the memory 130 in FIG. 1) may be connected to the second cover member 221. According to an embodiment, the second cover member 221 may protect components (e.g., the first circuit board 248 and the rear cover 223) located in the second housing 202 from external impact.

According to an embodiment, the rear cover 223 may protect components (e.g., the first circuit board 248) located on the second cover member 221. For example, the rear cover 223 may be connected to the second cover member 221 and formed to surround at least a portion of the first circuit board 248. According to an embodiment, the rear cover 223 may include an antenna pattern (e.g., at least one antenna element 223a) to communicate with an external electronic device. For example, when the rear cover 223 is formed as an injection molded product (e.g., an antenna carrier) of a dielectric material, the at least one antenna element 223a may be disposed on an outer surface (e.g., one surface facing the −Z axis direction). For example, the at least one antenna element 223a may include a laser direct structuring (LDS) antenna pattern formed on the outer surface of the rear cover 223. For example, the at least one antenna element 223a may be formed to be embedded during injection of the rear cover 223. For example, the at least one antenna element 223a may be configured to transmit or receive a wireless signal in a specified frequency band (e.g., a legacy band) by being electrically connected to a wireless communication circuit (e.g., the wireless communication module 192 in FIG. 1) disposed on the first circuit board 248.

According to an embodiment, the second rear plate 225 may substantially form at least a portion of the exterior of the second housing 202 or the electronic device 101. For example, the second rear plate 225 may be coupled to an outer surface of the second cover member 221. According to an embodiment, the second rear plate 225 may provide a decorative effect on the exterior of the electronic device 101. The second rear plate 225 may be manufactured using at least one of metal, glass, synthetic resin, or ceramic.

According to embodiments, the display assembly 230 may include a display 231 (e.g., the display 231 in FIGS. 2 and/or 3) and a multi-bar structure 232 supporting the display 203. According to an embodiment, the display 231 may be referred to as a flexible display, a foldable display, and/or a rollable display. According to an embodiment, the first display area A1 of the display 231 may be supported by a rigid body, and the second display area A2 may be supported by a bendable structure. For example, the first display area A1 may be supported by the first surface F1 of the second cover member 221 or a plate which is not shown. The second display area A2 may be supported by the multi-bar structure 232.

According to an embodiment, the multi-bar structure 232 may be connected or attached to at least a portion (e.g., the second display area A2) of the display 231. According to an embodiment, as the second housing 202 slides, the multi-bar structure 232 may move relative to the first housing 201. In the slide-in state (e.g., FIG. 2), most of the multi-bar structure 232 may be accommodated within the first housing 201 and located between the first cover member 211 and the second cover member 221. According to an embodiment, at least a portion of the multi-bar structure 232 may move in correspondence with the curved surface 213a located at an edge of the frame 213. According to an embodiment, the multi-bar structure 232 may be referred to as a display support member or a support structure, and have one elastic plate shape.

According to an embodiment, the driving structure 240 may move the second housing 202 relative to the first housing 201. For example, the driving structure 240 may include a motor 241 configured to generate a driving force, for example, for sliding the second housing 202 relative to the first housing. The driving structure 240 may include a gear 244 (e.g., a pinion) connected to the motor 241 and a rack 242 configured to mesh with the gear. Referring to FIG. 4, components (e.g., the motor 241, the rack 242, and the gear 244) of the driving structure 240 which is inverted (e.g., facing in the −Z-axis direction) are shown in a circle P1.

According to an embodiment, a housing in which the rack 242 is located may be different from a housing in which the motor 241 is located. According to an embodiment, the motor 241 may be connected to the second housing 202, and the rack 242 may be connected to the first housing 201. According to another embodiment, the motor 241 may be connected to the first housing 201, and the rack 242 may be connected to the second housing 202.

According to an embodiment, the motor 241 may be controlled by a processor (e.g., the processor 120 of FIG. 1). For example, the processor 120 may include a motor driver driving circuit and transmit a pulse width modulation (PWM) signal to the motor 241 to control the speed of the motor 241 and/or the torque of the motor 241. According to an embodiment, the motor 241 may be electrically connected to the processor (e.g., the processor 120 of FIG. 1) located on a circuit board (e.g., the first circuit board 248 of FIG. 4) using a flexible printed circuit board.

According to an embodiment, the second housing 202 may accommodate the first circuit board 248 (e.g., the main board). According to an embodiment, a processor, memory, and/or an interface may be mounted on the first circuit board 248. The processor may include, for example, one or more of a CPU, an AP, a GPU, an ISP, a sensor hub processor, or a CP. According to various embodiments, the first circuit board 248 may include a flexible printed circuit board type radio frequency cable (FRC). The first circuit board 248 may be disposed on at least a portion of the second cover member 221 and electrically connected to an antenna module and a communication module.

According to an embodiment, the memory may include, for example, volatile memory or non-volatile memory.

According to an embodiment, the interface may include, for example, an HDMI, a USB interface, an SD card interface, and/or an audio interface. For example, the interface may electrically or physically connect the electronic device 101 to an external electronic device and include a USB connector, an SD card/MMC connector, or an audio connector.

According to an embodiment, the electronic device 101 may include the second circuit board 245 (e.g., sub-circuit board) within the first housing 201, spaced apart from the first circuit board 248 (e.g., the main circuit board). The second circuit board 245 may be electrically connected to the first circuit board 248 through a connecting flexible board. The second circuit board 245 may be electrically connected to electrical components disposed in an end area of the electronic device 101, such as the battery 289 or a speaker and/or a SIM socket, to transmit signals and power. According to an embodiment, the second circuit board 249 may accommodate an antenna member 291 (e.g., a coil) or may be connected to the antenna member 291. The antenna member 291 may include a multi-function coil or multi-function core (MFC) antenna for performing a wireless charging function, a near field communication (NFC) function, and/or an electronic payment function. For example, the battery 289 may receive power from an external electronic device using the antenna member 291 for wireless charging. In another example, the battery 289 may transfer power to an external electronic device the antenna member 291 for wireless charging.

According to an embodiment, the battery 289, which is a device for supplying power to at least one component of the electronic device 101, may be a non-rechargeable primary battery, a rechargeable secondary battery, or a fuel cell. The battery 289 may be disposed integrally within the electronic device 101 or detachably from the electronic device 101. According to an embodiment, the battery 289 may be formed as a single integrated battery or include a plurality of separate batteries. According to an embodiment, the battery 289 may be located on the frame 213. For example, the battery 289 may be surrounded by the frame 213 and the battery cover 289a. According to another embodiment, the battery 289 may be located within the second housing 202 and slide together with the second housing 202.

According to an embodiment, the guide rail 250 may guide movement of the multi-bar structure 232. For example, the multi-bar structure 232 may slide along a slit 251 formed on the guide rail 250. According to an embodiment, the guide rail 250 may be connected to the first housing 201. For example, the guide rail 250 may be connected to the first cover member 211 and/or the frame 213. According to an embodiment, the slit 251 may be referred to as a groove or recess formed on an inner side surface of the guide rail 250. Referring to FIG. 4, the guide rail 250 is shown as enlarged in a circle P2.

According to an embodiment, the guide rail 250 may provide force to the multi-bar structure 232 based on driving of the motor 241.

According to an embodiment, when the electronic device 101 changes from the slide-in state to the slide-out state, at least a portion of the second housing 202 may slide to be exposed to the outside from the first housing 201 by driving the motor 241. For example, the gear 244 may rotate in a first rotation direction based on the driving of the motor 241. Since the rack 242 is fixed on the second cover member 221 of the second housing 202, the second housing 202 may slide to be exposed to the outside of the first housing 201 based on sliding of the rack 242 in a slide-out direction.

According to an embodiment, when the electronic device 101 changes from the slide-in state to the slide-out state, an inner portion 252 of the guide rail 250 may provide force to the multi-bar structure 232. The multi-bar structure 232 provided with the force may move along the slit 251 of the guide rail 250, and the second housing 202 may slide to extend relative to the first housing 201. At least a portion of the display assembly 230 accommodated between the first cover member 211 and the frame 213 may extend toward the front surface.

According to an embodiment, when the electronic device 101 changes from the slide-out state to the slide-in state, at least a portion of the second housing 202 may slide to be inserted into the first housing 201 through the driving of the motor 241. For example, the gear 244 may rotate in a second rotation direction opposite to the first rotation direction based on the driving of the motor 241. As the rack 242 is fixed on the second cover member 221 of the second housing 202, the second housing 202 may slide to enter the inside of the first housing 201 based on sliding of the rack 242 in a slide-in direction.

According to an embodiment, when the electronic device 101 changes from the slide-out state to the slide-in state, an outer portion 253 of the guide rail 250 may provide force to the bent multi-bar structure 232. The multi-bar structure 232 provided with the force may move along the slit 251 of the guide rail 250, and at least a portion of the second housing 202 may slide to be accommodated in the first housing 201. At least a portion of the display assembly 230 may be accommodated between the first cover member 211 and the frame 213.

According to an embodiment, the electronic device 101 may be configured to stop in a specified intermediate state between the slide-in state and the slide-out state by controlling the driving of the motor 241 (free stop function). According to an embodiment, the electronic device 101 may change to the slide-in state, the intermediate state, or the slide-out state through a user's manipulation in a state where no driving force is provided to the motor 241.

Referring to FIG. 5A, in the slide-in state of the electronic device 101, at least a portion of the second housing 202 may be disposed to be accommodated in the first housing 201. As the second housing 202 is disposed to be accommodated in the first housing 201, the overall volume of the electronic device 101 may be reduced. According to an embodiment, when the second housing 202 is accommodated in the first housing 201, the size of the visually exposed display 231 may be minimized. For example, when the second housing 202 is fully accommodated in the first housing 201, the first display area A1 of the display 231 may be visually exposed, and at least a portion (e.g., a portion facing the −Z axis) of the second display area A2 may be located between the battery 289 and the first rear plate 215.

Referring to FIG. 5B, when the electronic device 101 is in the slide-out state, at least a portion of the second housing 202 may protrude from the first housing 201. As the second housing 202 protrudes from the first housing 201, the overall volume of the electronic device 101 may increase. According to an embodiment, when the second housing 202 protrudes from the first housing 201, at least a portion of the second display area A2 of the display 231 may be visually exposed to the outside of the electronic device 101, together with the first display area A1.

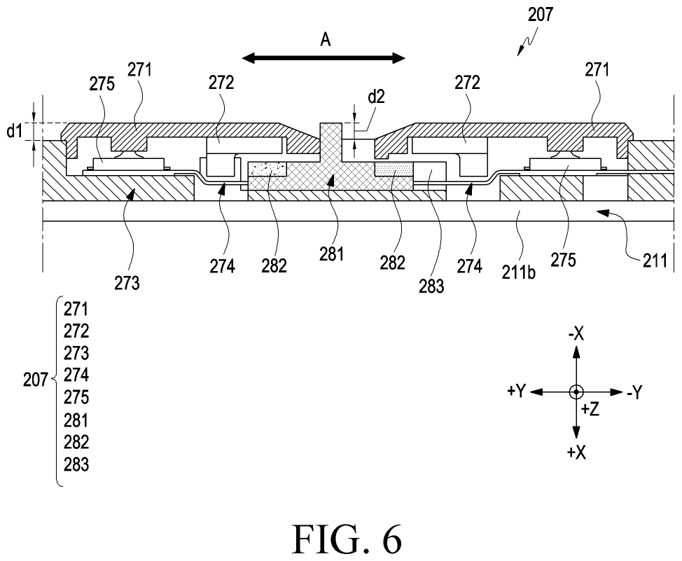

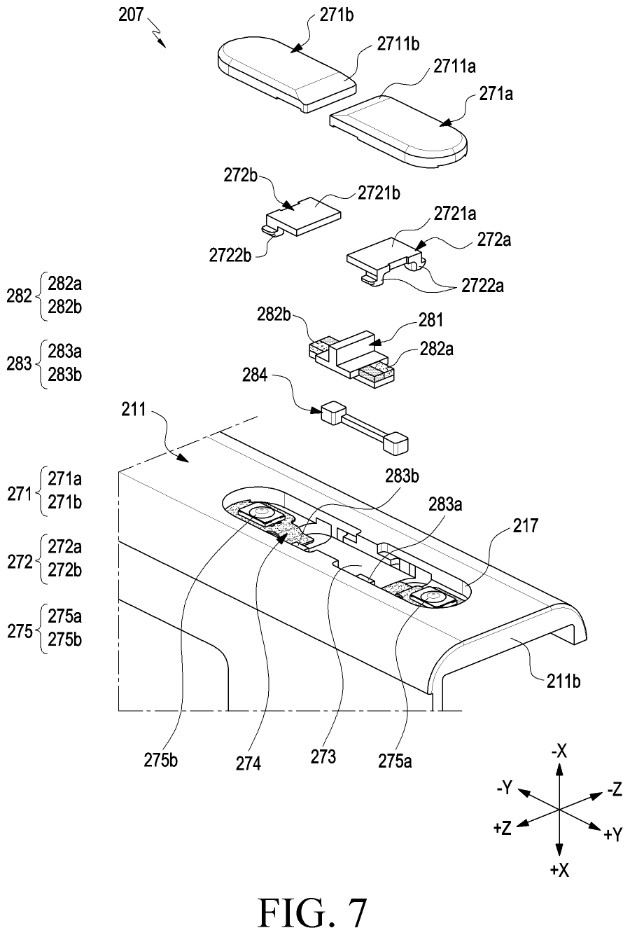

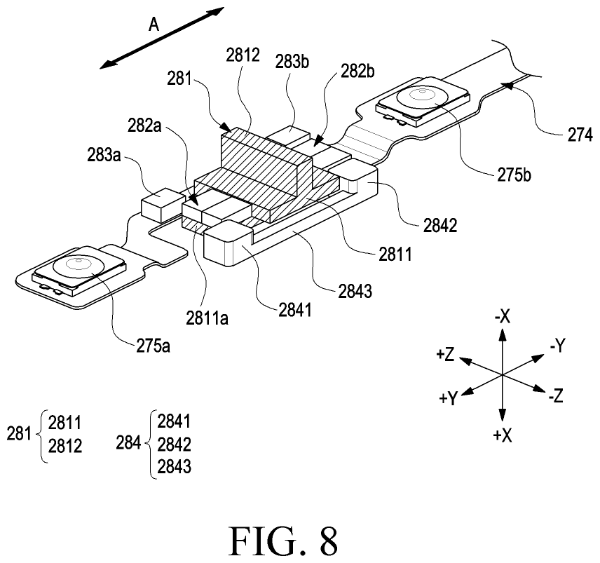

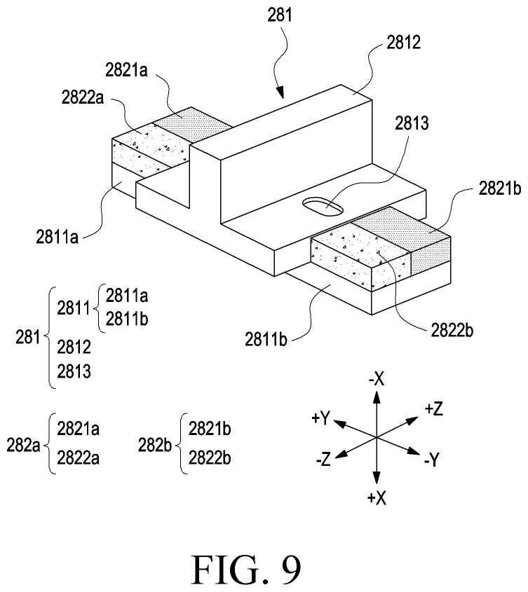

FIG. 6 is a cross-sectional view illustrating an electronic device and a key assembly, taken along line C-C′ of FIG. 2 according to an embodiment of the disclosure. FIG. 7 is an exploded perspective view illustrating a first cover member and a key assembly in an electronic device according to an embodiment of the disclosure. FIG. 8 is a perspective view illustrating a key assembly in an electronic device according to an embodiment of the disclosure. FIG. 9 is a diagram illustrating a function change key and a magnet in a key assembly according to an embodiment of the disclosure.

Referring to FIGS. 6 to 9, the electronic device 101 according to an embodiment may include at least one key assembly 207 (e.g., the first key assembly 249a and/or the second key assembly 249b of FIGS. 2 and 3) disposed in the first housing 201. In an embodiment, the key assembly 207 may be disposed on a portion of a sidewall (e.g., the (1-2)^{th} sidewall 211b or the (1-3)^{th} sidewall 211c of FIG. 2 or 3) of the first housing 201. According to an embodiment, the first housing 201 may include an accommodation hole (e.g., the accommodation hole 217 of FIG. 4) in which the key assembly 207 is disposed. For example, the accommodation hole 217 may be a hole penetrating from an outer surface to an inner surface of the (1-2)^{th} sidewall 211b of the first housing 201 to provide a space for accommodating the key assembly 207 therein. However, the shape of the accommodation hole 217 is not limited, and may be, for example, a recess formed from the outer surface toward the inner surface (e.g., in the +X direction). For example, the accommodation hole 217 may include an opening on the outer surface (e.g., the −X-direction surface) of the (1-2)^{th} sidewall 211b of the first housing 201, and the opening may have an elongated hole shape extending in the longitudinal direction (e.g., the Y-axis direction) of the electronic device 101.

In an embodiment, the key assembly 207 may include at least one key cover 271, at least one connecting member 272, a key support member 273, a key circuit board 274, at least one switch member 275, a function change key 281, at least one magnet 282, at least one Hall sensor 283, and/or a magnetic member 284.

In an embodiment, the outer surface (e.g., the −X direction surface) of the key cover 271 may be exposed to the outside of the electronic device 101 through the accommodation hole 217 of the first cover member 211, and form a portion of the exterior of the electronic device 101. According to an embodiment, the key cover 271 may be provided to transmit an external input to the first cover member 211 to the switch member 275 disposed on the inside of the key cover 271. In an embodiment, the key cover 271 may include a first key cover 271a and a second key cover 271b. The first key cover 271a and the second key cover 271b may be disposed at positions corresponding to a plurality of (e.g., two) switch members 275 that individually receive an external input (e.g., a click). For example, the external input may be applied in a click manner in which the user presses the key cover 271. In this case, the key cover 271 may be moved in at least one axial direction (e.g., the X-axis direction) by the external input that presses the key cover 271, and the external input may be transmitted by pressing the switch member 275 disposed inside the key cover 271. However, the method of applying an external input is not limited, and in addition to the click method, a method (e.g., touch method) using a sensor (e.g., the sensor module 176 of FIG. 1) may be applied.

According to an embodiment, the first key cover 271a and the second key cover 271b may be spaced apart from each other by a predetermined gap. According to an embodiment, the first key cover 271a and/or the second key cover 271b may include inclined areas 2711a and 2711b in areas facing each other. According to an embodiment, the first key cover 271a may include, at one end thereof facing the second key cover 271b, a first inclined area 2711a inclined toward the second key cover 271b and the inside of the electronic device 101. According to an embodiment, the second key cover 271b may include, at one end thereof facing the first key cover 271a, the first inclined area 2711a inclined toward the first key cover 271a and the inside of the electronic device 101. For example, the first inclined area 2711a and the second inclined area 2711b may be in a shape in which as they get closer to each other, they gather in a direction toward the inside of the electronic device 101. For example, the first inclined area 2711a and the second inclined area 2711b may be in a shape in which they are substantially symmetrical with each other. According to an embodiment, as described below, a second part 2812 of the function change key 281 may protrude from the space between the first key cover 271a and the second key cover 271b, and the first inclined area 2711a and the second inclined area 2711b may facilitate the user to grasp the second part 2812 of the function change key 281. For example, a distance (e.g., d1 in FIG. 7) by which each of the first key cover 271a and the second key cover 271b protrudes from the outer surface of the first cover member 211 of the electronic device 101 may be about 0.4 mm to about 0.6 mm, preferably about 0.5 mm.

In an embodiment, the connecting member 272 may be disposed between the key cover 271 and the key support member 273. According to an embodiment, the connecting member 272 may include a first connecting member 272a and a second connecting member 272b connected respectively to the first key cover 271a and the second key cover 271b. According to an embodiment, the connecting member 272 may movably connect the key cover 271 to the key support member 273 in at least one axial direction (e.g., the X-axis direction). For example, the connecting member 272 may include fixing portions 2721a and 2721b fixedly coupled or attached to the key cover 271. For example, an adhesive material may be provided between the key cover 271 and the fixing portions 2721a and 2721b. The connecting member 272 may include protruding portions 2722a and 2722b movably connected to the key support member 273 in at least one axial direction (e.g., the X-axis direction). For example, the protruding portions 2722a and 2722b may be accommodated in through holes formed in the key support member 273 at positions corresponding to the protruding portions 2722a and 2722b. For example, the key cover 271 and the connecting member 272 may be moved for a predetermined distance in one axial direction (e.g., the X-axis direction), for example, due to an external input (e.g., click), while the protruding portions of the connecting member 272 are accommodated in the through holes of the key support member 273.

In an embodiment, the key support member 273 may be disposed in the accommodation hole 217 of the first cover member 211. For example, the key support member 273 may provide an accommodation space for other components of the key assembly 207, together with the accommodation hole 217. For example, the key support member 273 may include a through hole or groove for accommodating some of the components of the key assembly 207. For example, other components of the key assembly 207 may be fixedly or semi-fixedly connected to the key support member 273. For example, the function change key 281 may be disposed on a portion of the key support member 273 to be slidable in at least one axial direction (e.g., the Y-axis direction). For example, at least a portion of a fixing member, the Hall sensor 283 and/or the magnetic member 284 may be accommodated in a through hole or groove formed at a corresponding position of the key support member 273. For example, the key support member 273 may have a shape corresponding to the accommodation hole 217, for example, a shape extending in the longitudinal direction (e.g., the Y-axis direction) of the electronic device 101.

In an embodiment, the key circuit board 274 may be disposed on one surface (e.g., an −X-axis direction surface) of the key support member 273. For example, the key circuit board 274 may include a flexible printed circuit board, and may be provided in a strip form. For example, the key circuit board 274 may be in a form in which at least a portion of a portion located on the (1-2)^{th} sidewall 211b extends in the longitudinal direction (e.g., the Y-axis direction) of the electronic device 101. According to an embodiment, the key circuit board 274 may be electrically connected to the main circuit board (e.g., the first circuit board 248 of FIG. 4) of the electronic device 101. For example, one end (e.g., a +Y-direction end) of the key circuit board 274 may be disposed on the (1-2)^{th} sidewall 211b, and the other end thereof, which is the opposite end of the one end, may extend toward the main circuit board (e.g., the first circuit board 248 of FIG. 4) of the electronic device 101, or vice versa. According to an embodiment, the at least one switch member 275 and/or the at least one Hall sensor 283 may be disposed on one surface (e.g., an −X direction surface) of the key circuit board 274 facing the key cover 271. According to an embodiment, the key circuit board 274 may transmit data regarding an external input (e.g., a click) detected by the switch member 275 or sliding of the function change key 281 detected by the Hall sensor 283 to a processor (e.g., the processor 120 of FIG. 1) disposed on the first circuit board 248, as described below.

In an embodiment, the switch member 275 of the key assembly 207 may be provided as a plurality of (e.g., two) switch members 275 that individually receive an external input (e.g., a click). In an embodiment, the switch member 275 may include a first switch member 275a and a second switch member 275b disposed on different areas of the key circuit board 274. For example, the first switch member 275a and the second switch member 275b may be spaced apart from each other in the longitudinal direction (e.g., the Y-axis direction) of the electronic device 101 and electrically connected to the key circuit board 274, respectively. For example, the first switch member 275a may be disposed in a first area of one surface (e.g., the −X-direction surface) of the key circuit board 274. The second switch member 275b may be disposed in a second area of the one surface (e.g., the −X-direction surface) of the circuit board, which does not overlap the first area. For example, the first area and the second area may be spaced apart from each other in the longitudinal direction (e.g., the Y-axis direction) of the electronic device 101. For example, the first switch member 275a and the second switch member 275b may be aligned with each other in one axial direction (e.g., the longitudinal direction or the Y-axis direction of the electronic device 101). For example, the first switch member 275a and/or the second switch member 275b may include a dome key structure or a tact switch structure. For example, the first switch member 275a and/or the second switch member 275b may be elastically deformed in a direction of applying an external input (e.g., a click) (e.g., the X-axis direction) and detect the external input, for example, by using a sensor (e.g., a piezoelectric element) disposed on the inside of the switch member.

In an embodiment, the function change key 281 of the key assembly 207 may be disposed on a portion of the key support member 273 to be slidable in at least one axial direction (e.g., a direction of an arrow A in FIG. 8). According to an embodiment, the function change key 281 may be disposed on a portion of one surface (e.g., the −X-direction surface) of the key support member 273. For example, the function change key 281 may be disposed between the first switch member 275a and the second switch member 275b, and may be provided to be slidable toward the first switch member 275a or the second switch member 275b. For example, a “sliding direction of the function change key 281” (e.g., FIG. 6 and a second Hall sensor value) may be substantially parallel to the direction (e.g., the Y-axis direction) in which the first switch member 275a and the second switch member 275b are spaced from each other, the sliding direction (e.g., the Y-axis direction or the direction of the arrow \textcircled{1} in FIG. 3) of the electronic device 101 (e.g., the electronic device 101 of FIGS. 2 to 4, 5A, and 5B), the longitudinal direction (e.g., the Y-axis direction) of the electronic device 101, and/or the Y-axis direction.

According to an embodiment, the function change key 281 may include a first part 2811 disposed inside the key assembly 207 and the second part 2812 protruding from a portion of the first part 2811. For example, the first part 2811 of the function change key 281 may be formed in a form that may be seated in the space between the key cover 271 and the key support member 273. According to an embodiment, the first part 2811 of the function change key 281 may include a first end 2811a facing the first switch member 275a and a second end 2811b facing the second switch member 275b as an opposite end of the first end 2811a. According to an embodiment, the at least one magnet 282 may be disposed on one surface (e.g., the −X-direction surface) of the first end 2811a and/or the second end 2811b of the function change key 281.

In an embodiment, the second part 2812 of the function change key 281 may be a protrusion extending from the first part 2811 toward the outside of the electronic device 101. Referring to FIG. 6, according to an embodiment, at least a portion of the second part 2812 of the function change key 281 may protrude to the outside of the electronic device 101 through the space between the first key cover 271a and the second key cover 271b that are spaced apart from each other. For example, the second part 2812 may extend or protrude in a direction (e.g., the −X direction) intersecting with the sliding direction (e.g., FIG. 6 and a second Hall sensor value) of the function change key 281 from a portion of the first part 2811. For example, the second part 2812 may be located between the first end 2811a and the second end 2811b of the first part 2811. For example, the extension or protrusion direction (e.g., the −X direction) of the second part 2812 may be substantially perpendicular to the sliding direction (e.g., FIG. 6 and a second Hall sensor value) or to one surface (e.g., the −X-direction surface) of the first part 2811.

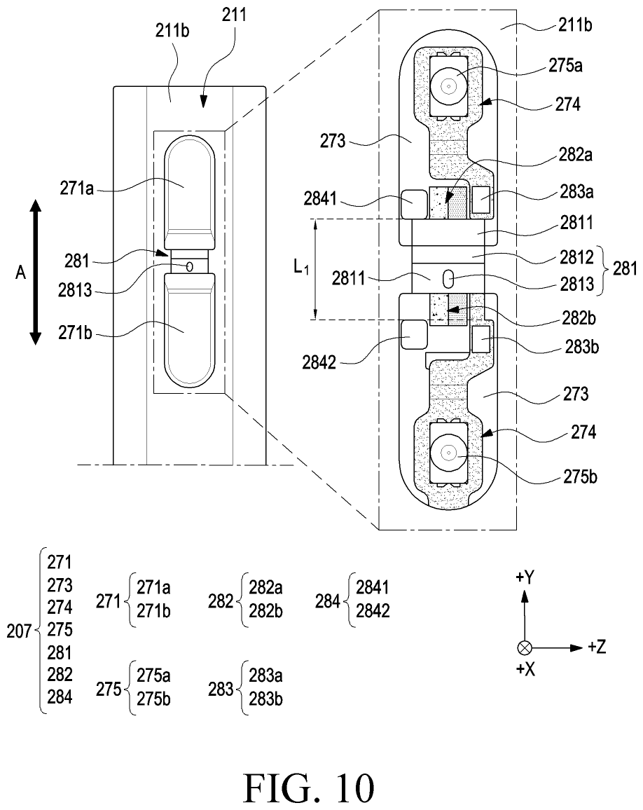

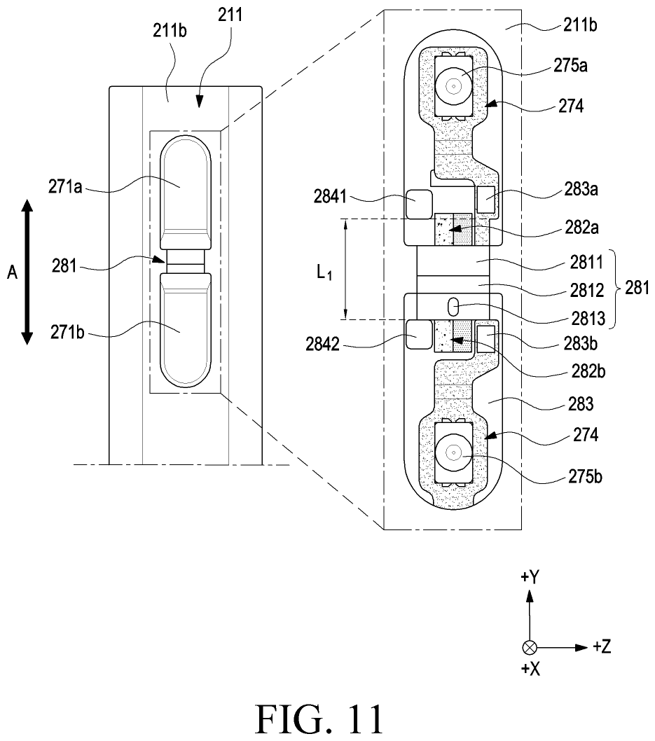

In an embodiment, the function change key 281 may be provided to be slidable between a first state and a second state. In the disclosure, the “first state” (e.g., see FIGS. 6 and 10) of the function change key 281 may refer to a state in which the first end 2811a of the function change key 281 is located closest or most adjacent to the first switch member 275a. In the disclosure, the “second state” (e.g., see FIGS. 8 and 11) of the function change key 281 may refer to a state in which the second end 2811b of the function change key 281 is located closest to the second switch member 275b. For example, the user may switch the function (e.g., volume control or display extension or reduction) of the key assembly 207 by sliding the function change key 281 between the first state and the second state by grasping or sliding the second part 2812 of the function change key 281 protruding outward from the electronic device 101, for example, with a finger or a nail.

According to an embodiment, a height (e.g., X-axis height) of an end (e.g., an −X-direction surface) of the second part 2812 may be substantially the same as or similar to a height (e.g., X-axis height) of the outer surface (e.g., the −X-direction surface) of the first key cover 271a and the second key cover 271b. For example, a distance (e.g., d2 in FIG. 6) by which the second part 2812 protrudes from the outer surface of the first cover member 211 of the electronic device 101 may be about 0.4 mm to about 0.6 mm, preferably about 0.5 mm. As described above, the first inclined area 2711a of the first key cover 271a and the second inclined area 2711b of the second key cover 271b may facilitate the user to grasp the second part 2812 of the function change key 281. For example, when the distances d1 and d2 by which the key covers 271 and the protrusion of the function change key 281 protrude from the outer surface of the first cover member 211 are substantially the same or similar to each other, and the inclined areas do not exist in the key covers 271, the difficulty of the user's action of grasping the function change key 281 may increase, compared to the case where the inclined areas exist according to an embodiment of the disclosure. For example, in the case where there are no inclined areas in the key covers 271, when the protrusion distance d2 of the function change key 281 from the outer surface of the first cover member 211 is formed to be greater than the protrusion distance d1 of the key covers 271 so that the user may easily grasp the function change key 281, unintentional movements of the second part 2812 excessively protruding outward from the electronic device 101 may increase, compared to the case where the distance d1 and the distance d2 are substantially the same or similar.

According to an embodiment, the at least one magnet 282 may be disposed on one end and/or the other end of the function change key 281. For example, the function change key 281 may include a recess or groove in which the magnet 282 may be accommodated on one surface (e.g., the −X direction surface) of one end and/or the other end of the first part 2811. For example, the area of the one end and/or the other end of the first part 2811 where the magnet 282 is disposed in the function change key 281 may be recessed by a specified step relative to another area of the first part 2811. For example, the step may be equal to or greater than a thickness (e.g., an X axis-direction thickness) of the magnet 282. According to an embodiment, a width (e.g., Z axis-direction width) of the magnet 282 may be smaller than a width (e.g., Z axis-direction width) of the first part 2811 of the function change key 281, and the area of the one end and/or the other end of the first part 2811 where the magnet 282 is disposed may have a width (e.g., Z axis-direction width) corresponding to the width of the magnet 282. For example, the width (e.g., Z axis-direction width) of the area of the one end and/or the other end of the first part 2811 that overlaps the magnet 282 on the X axis in the function change key 281 may be equal to or greater than the width (e.g., Z axis-direction width) of the magnet 282, and may be equal to or less than the width (e.g., Z axis-direction width) of the other area of the first part 2811.

In an embodiment, the magnet 282 of the key assembly 207 may include a first magnet 282a disposed on the first end 2811a of the function change key 281, which faces the first switch member 275a, and/or a second magnet 282b disposed on the second end 2811b of the function change key 281, which faces the second switch member 275b. For example, the first switch member 275a, the first magnet 282a, the function change key 281, the second magnet 282b, and/or the second switch member 275b may be aligned in one axial direction (e.g., the longitudinal direction or Y-axis direction) of the electronic device 101. According to an embodiment, when the function change key 281 slides, the first magnet 282a and the second magnet 282b may move together, and the at least one Hall sensor 283 may detect a magnetic flux change according to the movement of the magnet 282, as described below. The electronic device 101 may detect the position of the function change key 281 based on a measurement value of the Hall sensor 283. According to an embodiment, when the function change key 281 is in the first state, the first magnet 282a may face a first Hall sensor 283a, and when the function change key 281 is in the second state, the second magnet 282b may face a second Hall sensor 283b, as described below.

According to an embodiment, the first magnet 282a and the second magnet 282b may include a ferromagnetic substance 284, for example, they may be permanent magnets. In an embodiment, one portion of the first magnet 282a and/or the second magnet 282b may be an N-pole area, and the other portion thereof may be an S-pole area. In an embodiment, the N-pole area of the first magnet 282a and/or the second magnet 282b may be closer to the at least one Hall sensor 283 (e.g., the first Hall sensor 283a and/or the second Hall sensor 283b) than the S-pole area thereof, or vice versa.

Referring to FIG. 9, in an embodiment, the first magnet 282a may include a (1-1)^{th} magnet portion 2821a and a (1-2)^{th} magnet portion 2822a having different polarities. The (1-1)^{th} magnet portion 2821a may be closer to the first Hall sensor 283a than the (1-2)^{th} magnet portion 2822a. According to an embodiment, the (1-1)^{th} magnet portion 2821a and the (1-2)^{th} magnet portion 2822a may be disposed adjacent to each other in a direction (e.g., the Z-axis direction) intersecting the sliding direction A of the function change key 281. In an embodiment, the second magnet 282b may include a (2-1)^{th} magnet portion 2821b and a (2-2)^{th} magnet portion 2822b having different polarities. The (2-1)^{th} magnet portion 2821b may be closer to the second Hall sensor 283b than the (2-2)^{th} magnet portion 2822b. According to an embodiment, the (2-1)^{th} magnet portion 2821b and the (2-2)^{th} magnet portion 2822b may be disposed adjacent to each other in a direction (e.g., the Z-axis direction) intersecting the sliding direction A of the function change key 281. For example, when the function change key 281 is in the first state, the (1-1)^{th} magnet portion 2821a of the first magnet 282a may be disposed between the (1-2)^{th} magnet portion 2822a and the first Hall sensor 283a, as described below. Similarly, when the function change key 281 is in the second state, the (2-1)^{th} magnet portion 2821b of the second magnet 282b may be disposed between the (2-2)^{th} magnet portion 2822b and the second Hall sensor 283b.

In an embodiment, the (1-1)^{th} magnet portion 2821a and the (1-2)^{th} magnet portion 2821a may have the same polarity. In other words, the first magnet 282a and the second magnet 282b may be disposed so that their poles correspond to each other. For example, the (1-1)^{th} magnet portion 2821a and the (1-2)^{th} magnet portion 2822a of the first magnet 282a may be the N pole and the S pole, respectively, and the (2-1)^{th} magnet portion 2821b and the (2-2)^{th} magnet portion 2822b of the second magnet 282b may be the N pole and the S pole, respectively. Alternatively, the (1-1)^{th} magnet portion 2821a and the (1-2)^{th} magnet portion 2822a of the first magnet 282a may be the S pole and the N pole, respectively, and the (2-1)^{th} magnet portion 2821b and the (2-2)^{th} magnet portion 2822b of the second magnet 282b may be the S pole and the N pole, respectively.

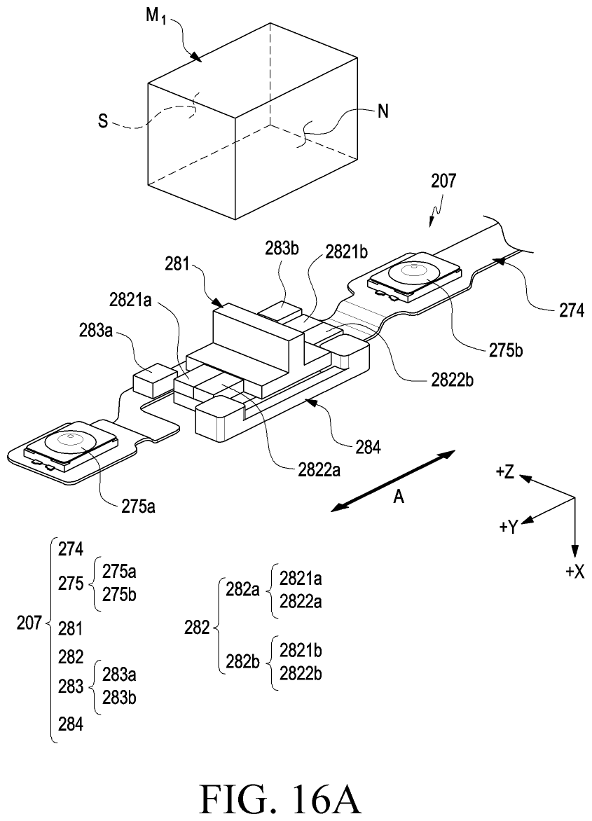

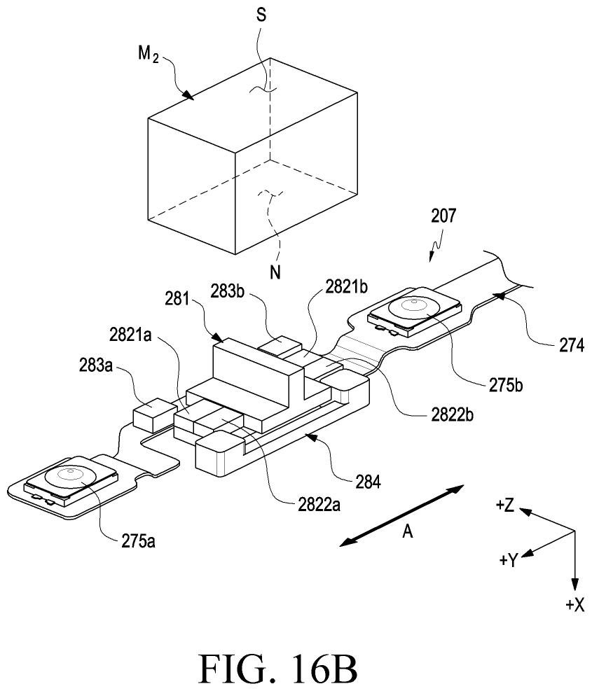

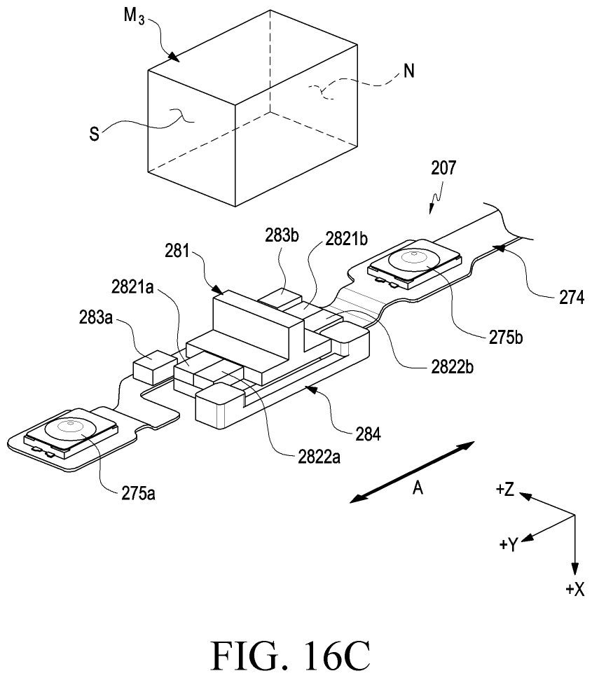

As described below with reference to FIGS. 16A to 16C, 17A to 17C, and 18A to 18C, when the first magnet 282a and the second magnet 282b are disposed with their poles corresponding to each other, the accuracy of detecting the first state or the second state of the function change key 281 may be improved even under the influence of an external magnetic force, in spite of the influence of magnetic fields of external magnets M1, M2, and M3 existing outside the electronic device 101. However, the polarities of the first magnet and the second magnet are not limited to those described above. For example, the first magnet 282a and the second magnet 282b may be disposed with their poles staggered. For example, the (1-1)^{th} magnet portion 2821a and the (1-2)^{th} magnet portion 2822a of the first magnet 282a may be the N pole and the S pole, respectively, and the (2-1)^{th} magnet portion 2821b and the (2-2)^{th} magnet portion 2822b of the second magnet 282b may be the S pole and the N pole, respectively. Alternatively, the (1-1)^{th} magnet portion 2821a and the (1-2)^{th} magnet portion 2822a of the first magnet 282a may be the S pole and the N pole, respectively, and the (2-1)^{th} magnet portion 2821b and the (2-2)^{th} magnet portion 2822b of the second magnet 282b may be the N pole and the S pole, respectively.

In an embodiment, the Hall sensor 283 of the key assembly 207 may include the first Hall sensor 283a and the second Hall sensor 283b disposed on different areas of the key circuit board 274. For example, the first Hall sensor 283a and the second Hall sensor 283b may be disposed spaced apart from each other in the longitudinal direction (e.g., the Y-axis direction) of the electronic device 101 and electrically connected to the key circuit board 274, respectively. For example, the first Hall sensor 283a may be disposed on a third area of one surface (e.g., the −X-direction surface) of the key circuit board 274. The second Hall sensor 283b may be disposed on a fourth area of the one surface (e.g., the −X-direction surface) of the circuit board, which does not overlap the third area. For example, the third area in which the first Hall sensor 283a is disposed and the fourth area in which the second Hall sensor 283b is disposed may be located between the first area and the second area on the one surface (e.g., the −X-direction surface) of the circuit board, in which the switch members 275 are disposed. For example, the third area in which the first Hall sensor 283a is disposed and the fourth area in which the second Hall sensor 283b is disposed may be spaced apart from each other in the longitudinal direction (e.g., the Y-axis direction) of the electronic device 101. For example, the first Hall sensor 283a and the second Hall sensor 283b may be aligned with each other in one axial direction (e.g., the longitudinal direction or the Y-axis direction) of the electronic device 101.

In an embodiment, the first Hall sensor 283a and the second Hall sensor 283b may provide their measurement values regarding the movement or position of the function change key 281 to the processor (e.g., the processor 120 of FIG. 1) electrically connected through the key circuit board 274, respectively. For example, the first Hall sensor 283a and the second Hall sensor 283b may include Hall elements that measure the strengths of magnetic fields, magnetic flux densities, and/or magnetic fluxes or magnetic flux changes of the first magnet 282a and the second magnet 282b that move together when the function change key 281 slides. According to an embodiment, when the function change key 281 is in the first state, the first Hall sensor 283a may face the first magnet 282a, and when the function change key 281 is in the second state, the second Hall sensor 283b may face the second magnet 282b.

In an embodiment, the magnetic member 284 of the key assembly 207 may be disposed on a portion of the key support member 273. For example, the magnetic member 284 may be located to face at least a portion of a side surface (e.g., a −Z-direction side surface) of the function change key 281. According to an embodiment, the magnetic member 284 of the key assembly 207 may be located to face the Hall sensors 283 with the function change key 281 interposed therebetween. According to an embodiment, the magnetic member 284 may include a material that is magnetized by a magnetic field of the magnet 282 (e.g., the first magnet 282a or the second magnet 282b). For example, the magnetic member 284 may include a magnetic substance, such as iron. In an embodiment, the magnetic member 284 may include a first magnetic end 2841 facing the first magnet 282a when the function change key 281 is in the first state, a second magnetic end 2842 facing the second magnet 282b when the function change key 281 is in the second state, and a connecting portion 2843 connecting the two ends 2841 and 2842. For example, when the function change key 281 is in the first state, the first magnet 282a may be disposed between the first magnetic end 2841 and the first Hall sensor 283a, and when the function change key 281 is in the second state, the second magnet 282b may be disposed between the second magnetic end 2842 and the second Hall sensor 283b. For example, the connecting portion 2843 of the magnetic member 284 may be in a form that extends in the sliding direction (e.g., FIG. 6 and a second Hall sensor value) of the function change key 281. For example, the magnetic member 284 may be formed so that at least the first magnetic end 2841 and the second magnetic end 2842 include a magnetic material, and according to an embodiment, the entire magnetic member 284 may be formed to include a magnetic material. According to an embodiment (not shown), the connecting portion 2843 may be omitted, and the first magnetic end 2841 and the second magnetic end 2842 may be provided as separate magnetic members 284.

According to an embodiment, when the function change key 281 moves to the first state, the first magnet 282a disposed at the first end 2811a of the function change key 281 approaches the first magnetic end 2841, and thus a magnetic force may be applied between the first magnetic end 2841 and the first magnet 282a. The magnetic force may act as an attractive force that pulls the function change key 281 to be placed in the first state. Similarly, when the function change key 281 moves to the second state, the second magnet 282b disposed at the second end 2811b of the function change key 281 approaches the second magnetic end 2842, and thus a magnetic force may be applied between the second magnetic end 2842 and the second magnet 282b. The magnetic force may act as an attractive force that pulls the function change key 281 to be placed in the second state. The attractive force of the magnetic member 284 may allow the user to haptically sense whether the function change key 281 is close to or disposed in the first state or the second state. The magnetic member 284 may provide a physical key operation feeling of the function change key 281 being pulled to the first state or the second state, thereby helping the user intuitively operate the function change key 281. When the function change key 281 in the first state or the second state is unintentionally moved by an external force, the attractive force of the magnetic member 284 may act as a repulsive force, thereby reducing malfunction.

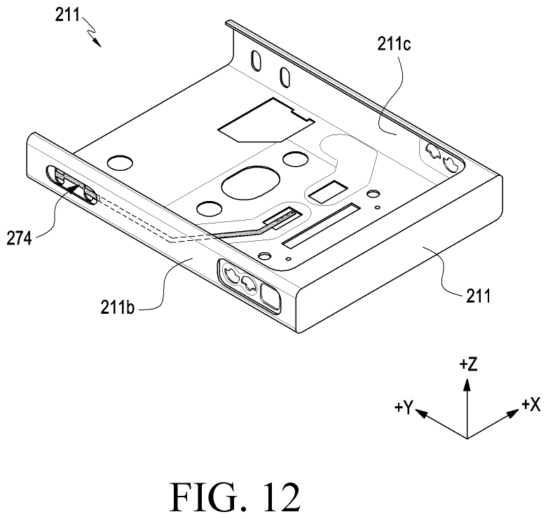

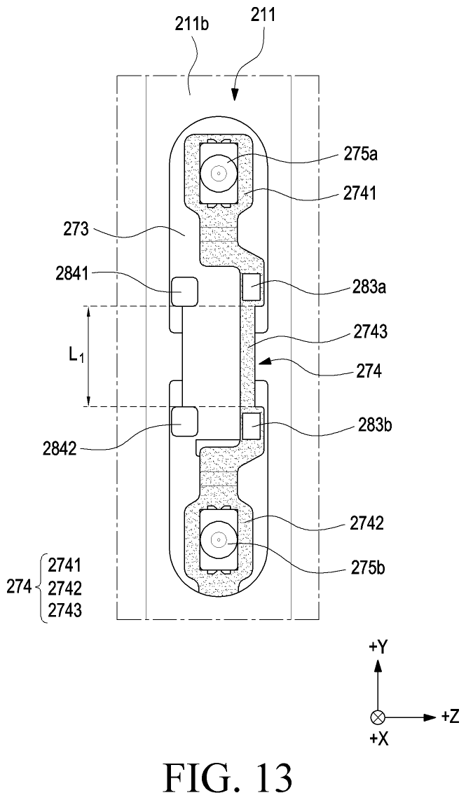

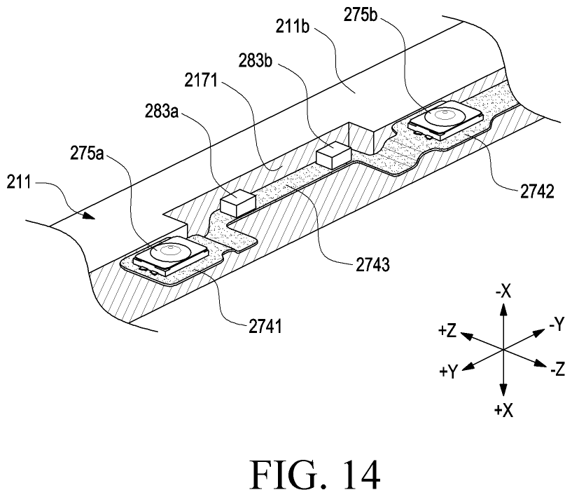

FIG. 10 is a plan view illustrating a key assembly, when a function change key is in a first state according to an embodiment of the disclosure. FIG. 11 is a plan view illustrating a key assembly, when a function change key is in a second state according to an embodiment of the disclosure. FIG. 12 is a perspective view illustrating a first cover member and a key circuit board of a key assembly in an electronic device according to an embodiment of the disclosure. FIG. 13 is a plan view illustrating a first cover member and some components of a key assembly in an electronic device according to an embodiment of the disclosure. FIG. 14 is a perspective view illustrating a first cover member and some components of a key assembly in an electronic device according to an embodiment of the disclosure.

FIGS. 10 and 11 are plan views illustrating the function change key 281 in the first state and the second state, with the key cover 271 mounted thereon, and enlarged plan views illustrating the function change key 281 in the first state and the second state, with the key cover 271 removed therefrom, according to an embodiment. For the key assembly 207 of FIGS. 10 and 11, the key assembly 207 of FIGS. 6 to 9 may be referred to.

According to an embodiment of the disclosure, the electronic device 101 may detect whether the function change key 281 is in the first state or the second state, using the first Hall sensor 283a and the second Hall sensor 283b, and provide set functions (e.g., volume control and display extension or reduction) of the key assembly 207 corresponding to the first state and the second state.

In an embodiment, the function change key 281 of the key assembly 207 may include a position indicator 2813 on at least a portion of the first part According to an embodiment, the position indicator 2813 may be located at a position that may be visible to or concealed from the outside of the electronic device 101 depending on the first state or the second state of the function change key 281, thereby allowing the user to visually recognize the position of the function change key 281 and a set function of the key assembly 207 accordingly. For example, the function change key 281 may be visible to the outside of the electronic device 101 or the key assembly 207 in the first state and concealed inside the electronic device 101 or the key assembly 207 in the second state. In this case, the user may recognize that the function change key 281 is in the first state by looking at the position indicator 2813. Conversely, according to an embodiment (not shown), the function change key 281 may be concealed inside the electronic device 101 or the key assembly 207 in the first state and visible to the outside of the electronic device 101 or the key assembly 207 in the second state. In this case, the user may recognize that the function change key 281 is in the second state by looking at the position indicator 2813.

According to an embodiment, the position indicator 2813 may be formed on a portion of a surface (e.g., the −X-direction surface) of the first part 2811 (e.g., the first part 2811 of FIGS. 8 and 9) of the function change key 281, which faces the key covers 271. For example, the position indicator 2813 may be formed on the surface (e.g., the −X-direction surface) of the first part 2811 located between the second part 2812 (e.g., the second part 2812 of FIGS. 8 and 9) of the function change key 281 and the second end 2811b (e.g., the second end 2811b of FIGS. 8 and 9) of the first part 2811. However, the arrangement of the position indicator 2813 is not limited to that described above, and for example, the position indicator 2813 may be formed on one surface (e.g., the −X-direction surface) of the first part 2811 located between the second part 2812 and the first end 2811a of the function change key 281. According to an embodiment, the position indicator 2813 may be omitted. For example, the position indicator 2813 may be displayed on the surface of the first part 2811 in various designs such as various figures (e.g., line, circle, oval, and polygon), pictures, letters, or combinations thereof, in an intaglio or relief manner, and may be displayed in a color that is distinct from the other portion of the function change key 281.

Referring to FIGS. 10 and 11, a length L1 of a slide area in which the function change key 281 is disposed to be slidable on the key support member 273 may be about 1 mm to about 1.5 mm. According to an embodiment, the length L1 may be about 1.2 mm. For example, the “slide area” may be an area of the key support member 273, in which the function change key 281 is disposed, and may be an area of the key support member 273 that overlaps the function change key 281 in the width direction (e.g., the X-axis direction) of the electronic device 101. For example, the “length L1” may refer to the length of the slide area measured in the sliding direction A of the function change key 281. For example, the length L1 may be substantially equal to a gap between the first magnetic end 2841 and the second magnetic end 2842. For example, a displacement of the function change key 281 in the sliding direction A may be determined according to the gap between the first key cover 271a and the second key cover 271b. For example, the length L1 may be determined by the gap between the first magnetic end 2841 and the second magnetic end 2842 and/or the gap between the first key cover 271a and the second key cover 271b.

Referring to FIG. 12, the key circuit board 274 of the key assembly 207 may include a portion disposed on a portion (e.g., the (1-2)^{th} sidewall 211b) of the first cover member 211 and a portion connected to the main circuit board (e.g., the first circuit board 248). For example, one end (e.g., a +Y-direction end) of the key circuit board 274 may be disposed on the (1-2)^{th} sidewall 211b, and the other end thereof, which is the opposite end of the one end, may be formed to extend toward the main circuit board (e.g., the first circuit board 248 of FIG. 4) of the electronic device 101. For example, the other end of the key circuit board 274 may be electrically connected to the first circuit board. For example, the other end of the key circuit board 274 may be disposed on a portion of an inner surface (e.g., a +Z-direction surface) of the first cover member 211 and may at least partially overlap the first circuit board 248 in the thickness direction (e.g., the Z-axis direction) of the electronic device 101. For example, a portion between the two ends of the key circuit board 274 may be formed on the inner surface of the first cover member 211 to prevent interference with other electrical bodies disposed on the first cover member 211. Obviously, depending on the arrangement of the key assembly 207 and the arrangement relationship with the first circuit board (e.g., the first circuit board 248 of FIG. 4), one end (e.g., the −Y direction end) of the key circuit board 274 may be disposed on the (1-2)^{th} sidewall 211b, and the other end, which is the opposite end of the one end, may be formed to extend toward the main circuit board (e.g., the first circuit board 248 of FIG. 4) of the electronic device 101. In an embodiment, a plurality of switch members 275 and a plurality of Hall sensors 283 may be disposed on and electrically connected to the key circuit board 274. According to an embodiment, the key circuit board 274 may be configured to transmit a signal regarding an external input (e.g., a click) applied to the first switch member 275a and/or the second switch member 275b or sliding of the function change key 281 detected by the Hall sensor 283 to the processor (e.g., the processor 120 of FIG. 1) disposed on the first circuit board 248.

In the following description given with reference to FIGS. 13 and 14, the key circuit board 274 may be referred to as a plurality of substrate portions 2741, 2742, and 2743, but this division is for convenience of description, and the substrate portions 2741, 2742, and 2743 may be configured integrally. For example, the key circuit board 274 may include a first substrate portion 2741 on which the first switch member 275a is disposed, a second substrate portion 2742 on which the second switch member 275b is disposed, and a third substrate portion 2743 connecting the first substrate portion 2741 and the second substrate portion 2742, in an area disposed on the key support member 273. According to an embodiment, the first Hall sensor 283a and the second Hall sensor 283b may be disposed on the third substrate portion 2743, and an area between portions in which the Hall sensors 283 are disposed may at least partially overlap in a direction (e.g., the width direction or X-axis direction) of the electronic device 101 intersecting the function change key 281 and the sliding direction (e.g., the direction of the arrow A in FIGS. 10 and 11) of the function change key 281. For example, the first substrate portion 2741 may include one end of the key circuit board 274, and the second substrate portion 2742 may be connected to the other end of the key circuit board 274 connected to the main circuit board (e.g., the first circuit board 248 of FIG. 4). For example, the “sliding direction of the function change key 281” (e.g., the direction of the arrow A in FIGS. 10 and 11) may be substantially parallel to the direction (e.g., the Y-axis direction) in which the first switch member 275a and the second switch member 275b are spaced from each other, the sliding direction (e.g., the Y-axis direction or the direction of the arrow \textcircled{1} in FIG. 3) of the electronic device 101 (e.g., the electronic device 101 of FIGS. 2 to 4, 5A, and 5B), the longitudinal direction (e.g., the Y-axis direction) of the electronic device 101, and/or the Y-axis direction.

According to an embodiment, the shape of the third substrate portion 2743 may be formed so as not to overlap the magnetic member 284 that slides together with the function change key 281. Referring to FIGS. 11 and 13, in an embodiment, the third substrate portion 2743 may not overlap the first magnetic member 284 and the second magnetic member 284 in a direction (e.g., the width direction or the X-axis direction of the electronic device 101) intersecting the sliding direction A of the function change key 281.

According to an embodiment, the third substrate portion 2743 may include a portion that is bent outward (e.g., the +X direction) from the first substrate portion 2741 and the second substrate portion 2742 so as not to be aligned with the function change key 281 in the sliding direction A. For example, portions of the third substrate part 2743 connected to the first substrate portion 2741 and the second substrate portion 2742 may have a shape that us bent in a direction (e.g., the height direction or the Z-axis direction of the electronic device 101) intersecting the sliding direction A, for example, a ‘┐’ or ‘└’ shape. The Hall sensors 283 disposed on the third substrate portion 2743 may not be aligned with the switch members 275 and/or the function change key 281 in the sliding direction A of the function change key 281. For example, the third substrate portion 2743 may be formed such that a portion of the third substrate portion 2743 overlapping the slide area on the key support member 273 in which the function change key 281 is slidable has a narrower width (e.g., Z axis-direction width) than the other portion. According to an embodiment, the length L1 of the slide area may be about 1 mm to about 1.5 mm, for example, about 1.2 mm.

Referring to FIG. 14, the first cover member 211 may include a mounting area 2171 that accommodates the third substrate portion 2743 having a protruding shape relative to the first substrate portion 2741 and the second substrate portion 2742. For example, the mounting area 2171 of the first cover member 211 in which the third substrate portion 2743 is disposed may be a recessed area formed to correspond to the shape of the third substrate portion 2743. According to an embodiment of the disclosure, when the key circuit board 274 and the magnetic member 284 do not overlap in a direction (e.g., the width direction or X-axis direction of the electronic device 101) intersecting the sliding direction A, the electromagnetic influence of the magnetic member 284 that slides on electrical bodies disposed on the key circuit board 274 may be reduced, compared to the case where they are disposed to overlap each other.

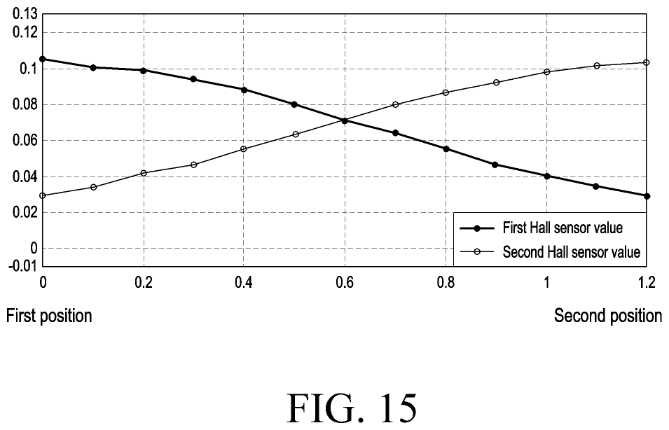

FIG. 15 is graphs of first Hall sensor values and second Hall sensor values according to positions of a function change key in a key assembly according to an embodiment of the disclosure.

According to an embodiment, the length (e.g., L1 of FIGS. 10, 11, and 13) of an area in which the function change key 281 is slidable on the key support member 273 may be about 1.2 mm. The X axis in FIG. 15 represents the position of the function change key 281, which may correspond to 0 in the first state (e.g., see FIG. 10), and 1.2 (unit: mm) in the second state (e.g., see FIG. 11). The position of the function change key 281 between the first state and the second state may correspond to a value between 0 and 1.2. However, the length L1 is not limited, and may be changed, for example, depending on the arrangement of the key cover 271 and the function change key 281. The Y axis in FIG. 15 may represent magnetic flux values (unit: weber (wb)=1T·m²) of the magnets (e.g., the first magnet 282a and the second magnet 282b of FIGS. 10 and 11), as measurement values of the first Hall sensor 283a and measurement values of the second Hall sensor 283b.

According to an embodiment, as the first magnetic member 284 is closer to the first Hall sensor 283a, the measurement value of the first Hall sensor 283a (or “first Hall sensor value”) may increase, whereas as the second magnetic member 284 is closer to the second Hall sensor 283b, the measurement value (or “second Hall sensor value”) of the second Hall sensor 283b may increase. Referring to FIG. 15, when the function change key 281 is in the first state, the first magnetic member 284 is closest to the first Hall sensor 283a. Accordingly, when the function change key 281 is in the first state, the first Hall sensor value may be a maximum value. When the function change key 281 is in the first state, the second magnetic member 284 is farthest from the second Hall sensor 283b, and thus the second Hall sensor value may be a minimum value. When the function change key 281 moves from the first state to the second state, the first magnetic member 284 moves away from the first Hall sensor 283a, and thus the first Hall sensor value may decrease, whereas the second magnetic member moves closer to the second Hall sensor 283b, and thus the second Hall sensor value may increase. When the function change key 281 is in the second state, the first magnetic member 284 is farthest from the first Hall sensor 283a, and thus the first Hall sensor value may be a minimum value. When the function change key 281 is in the second state, the second magnetic member 284 is closest to the second Hall sensor 283b, and thus the second Hall sensor value may be a maximum value. For example, the maximum value of the first Hall sensor 283a or the second Hall sensor 283b may be about 0.1 or more and about 0.12 or less, and the minimum value thereof may be about 0.02 or more and about 0.04 or less. As the function change key 281 moves between the first state and the second state, the first Hall sensor value and the second Hall sensor value may continuously increase or decrease between the respective minimum and maximum values.

FIG. 16A is a perspective view illustrating an operation of a key assembly in the presence of an external magnet around an electronic device according to an embodiment of the disclosure. FIG. 16B is a perspective view illustrating an operation of a key assembly in the presence of an external magnet around an electronic device according to an embodiment of the disclosure. FIG. 16C is a perspective view illustrating an operation of a key assembly in the presence of an external magnet around an electronic device according to an embodiment of the disclosure.

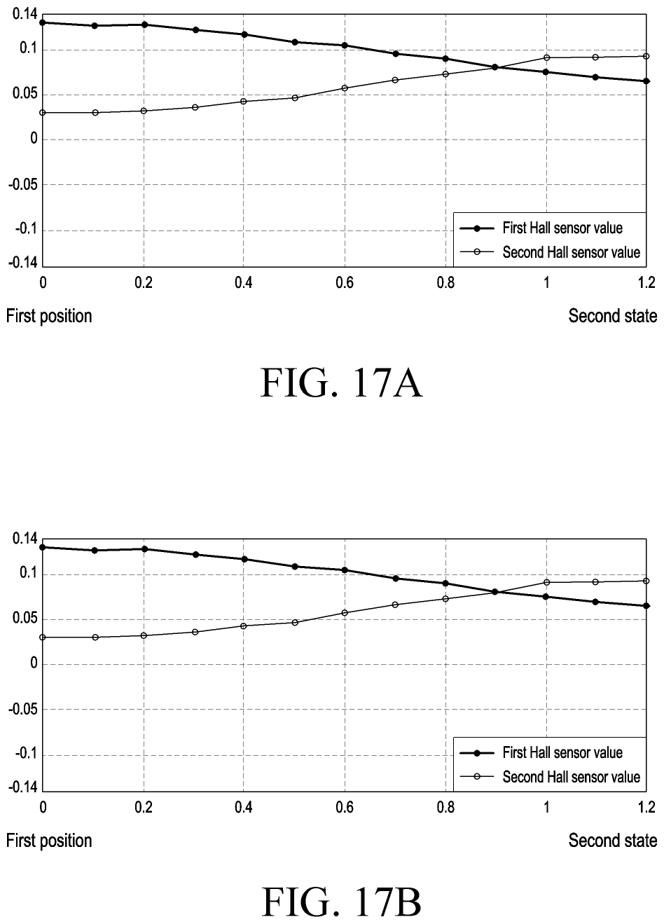

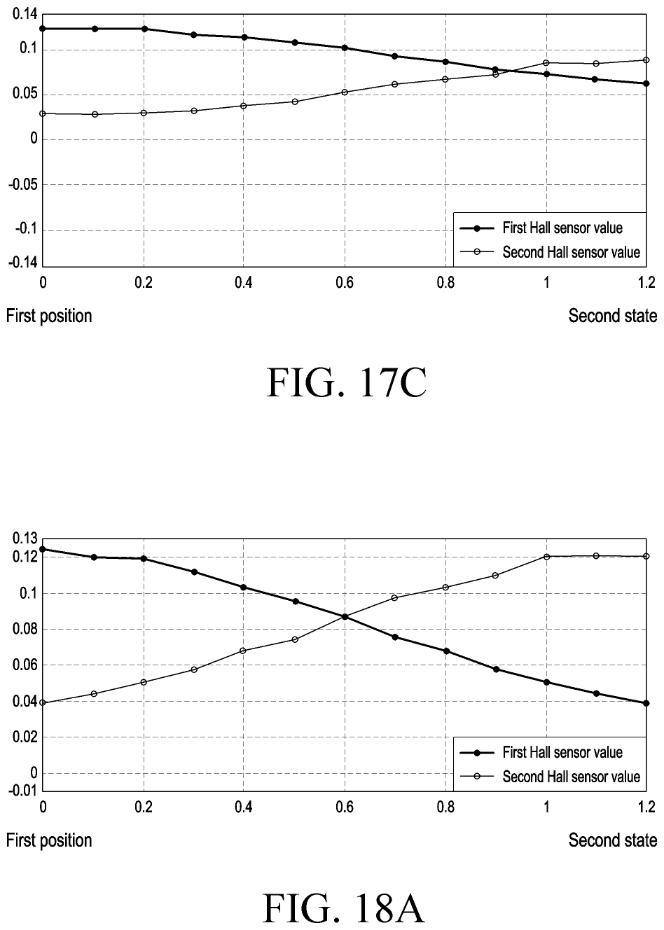

FIG. 17A is graphs of first Hall sensor values and second Hall sensor values according to positions of the function change key in the key assembly of FIG. 16A according to an embodiment of the disclosure. FIG. 17B is graphs of first Hall sensor values and second Hall sensor values according to positions of the function change key in the key assembly of FIG. 16B according to an embodiment of the disclosure. FIG. 17C is graphs of first Hall sensor values and second Hall sensor values according to positions of the function change key in the key assembly of FIG. 16C according to an embodiment of the disclosure.

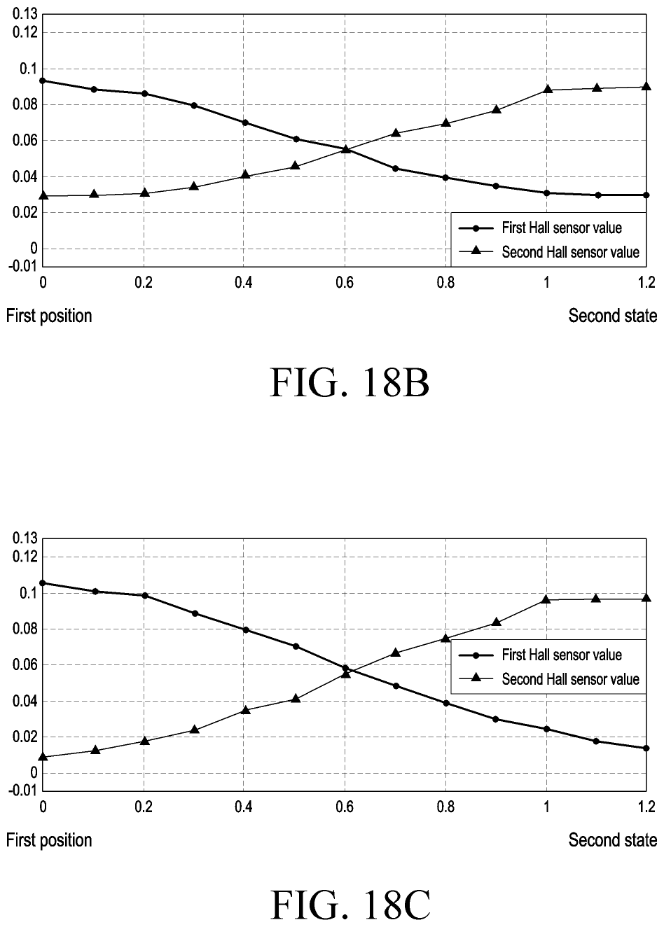

FIG. 18A is graphs of first Hall sensor values and second Hall sensor values according to positions of the function change key in the key assembly of FIG. 16A according to an embodiment of the disclosure. FIG. 18B is graphs of first Hall sensor values and second Hall sensor values according to positions of the function change key in the key assembly of FIG. 16B according to an embodiment of the disclosure. FIG. 18C is graphs of first Hall sensor values and second Hall sensor values according to positions of the function change key in the key assembly of FIG. 16C according to an embodiment of the disclosure.

Referring to FIGS. 16A to 16C, the key assembly 207 may include the key circuit board 274, the switch member 275, the function change key 281, the magnet 282, the Hall sensor 283, and the magnetic member 284. For the key assembly 207 of FIGS. 16A to 16C, reference may be made to the key assembly 207 of FIGS. 6 and 7, and the key cover 271, the connecting member 272, and the key support member 273 of the key assembly 207 may be omitted in FIGS. 16A to 16C. For the key circuit board 274, the switch member 275, the function change key 281, the magnet 282, the Hall sensor 283, and the magnetic member 284 of FIGS. 16A to 16C, reference may be made to the key circuit board 274, the switch member 275, the function change key 281, the magnet 282, the Hall sensor 283, and the magnetic member 284 of FIGS. 7, 8, 10, and 11. The description given with reference to the embodiment of FIGS. 5A, 5B, and 6 to 15 may be equally applied to the key assembly 207 of FIGS. 16A to 16C, and a redundant description will be avoided below.

According to an embodiment, the position of the magnet 282 that slides together with the function change key 281 may be detected using a magnetic flux change measured by the Hall sensor 283. For example, when a large magnetic field existing around the electronic device 101 (e.g., the electronic device 101 of FIG. 1 and/or the electronic device 101 of FIGS. 2 to 4, 5A, and 5B) or the key assembly 207 affects the magnetic flux value of the Hall sensor 283, the accuracy of the value of the Hall sensor 283 may decrease, and the electronic device 101 may malfunction due to the disturbed measurement value of the Hall sensor 283. For example, as illustrated in FIGS. 16A to 16C, it may be assumed that a magnet 282 having a sufficiently large magnetic force exists outside the electronic device 101 or the key assembly 207.

FIGS. 17A to 17C illustrate measurement values of the first Hall sensor 283a (or “first Hall sensor values”) and measurement values of the second Hall sensor 283b (or “second Hall sensor values”), when the first magnet 282a and the second magnet 282b are disposed with their poles staggered with each other in the key assembly 207 according to an embodiment of the disclosure. For example, referring to FIGS. 16A to 16C, when the poles of the first magnet 282a and the second magnet 282b are disposed to be staggered with each other, the (1-1)^{th} magnet portion 2821a and the (1-2)^{th} magnet portion 2822a of the first magnet 282a may be the N pole and the S pole, respectively, and the (2-1)^{th} magnet portion 2821b and the (2-2)^{th} magnet portion 2822b of the second magnet 282b may be the S pole and the N pole, respectively. Alternatively, the (1-1)^{th} magnet portion 2821a and the (1-2)^{th} magnet portion 2822a of the first magnet 282a may be the S pole and the N pole, respectively, and the (2-1)^{th} magnet portion 2821b and the (2-2)^{th} magnet portion 2822b of the second magnet 282b may be the N pole and the S pole, respectively. When the first magnet 282a and the second magnet 282b are disposed with their poles staggered with each other, a reference for an existing first threshold may be distorted due to the magnetic fields of external magnets M1, M2, and M3 existing outside the electronic device 101, and the symmetry of the first Hall sensor values and the second Hall sensor values may change.

FIGS. 18A to 18C illustrate measurement values of the first Hall sensor 283a (or “first Hall sensor values”) and measurement values of the second Hall sensor 283b (or “second Hall sensor values”), when the first magnet 282a and the second magnet 282b are disposed with their poles corresponding to each other in the key assembly 207 according to an embodiment of the disclosure. For example, referring to FIGS. 16A to 16C, when the first magnet 282a and the second magnet 282b are disposed with their poles corresponding to each other, the (1-1)^{th} magnet portion 2821a (e.g., the (1-1)^{th} magnet portion 2821a of FIG. 9) the first magnet 282a and the (1-2)^{th} magnet portion 2822a (e.g., the (1-2)^{th} magnet portion 2822a of FIG. 9) may be the N pole and the S pole, respectively, and the (2-1)^{th} magnet portion 2821b (e.g., the (2-1)^{th} magnet portion 2821b of FIG. 9) and the (2-2)^{th} magnet portion 2822b (e.g., the (2-2)^{th} magnet portion 2822b of FIG. 9) may be the N pole and the S pole, respectively. Alternatively, the (1-1)^{th} magnet portion 2821a and the (1-2)^{th} magnet portion 2822a of the first magnet 282a may be the S pole and the N pole, respectively, and the (2-1)^{th} magnet portion 2821b and the (2-2)^{th} magnet portion 2822b of the second magnet 282b may be the S pole and the N pole, respectively. According to an embodiment, when the poles of the first magnet 282a and the second magnet 282b are disposed to correspond to each other, a change in a magnetic flux value may occur due to the influence of the magnetic fields of the external magnets M1, M2, and M3 existing outside the electronic device 101, but the symmetry of the first Hall sensor values and the second Hall sensor values may be maintained. For example, the processor (e.g., the processor 120 of FIG. 1) of the electronic device 101 may determine the position of the function change key 281 by relatively comparing a first Hall sensor value and a second Hall sensor value and correcting the first Hall sensor value and the first Hall sensor value using the existing first threshold. For example, when a ratio of the second Hall sensor value to the first Hall sensor value is equal to or greater than a second threshold, the processor (e.g., processor 120 of FIG. 1) may determine that the function change key 281 is in the first state. For example, when the ratio of the second Hall sensor value to the first Hall sensor value is equal to or less than a third threshold, the processor may also determine that the function change key 281 is in the second state. In a comparison between the embodiments of FIGS. 17A to 17C and FIGS. 18A to 18C, when the magnets 282 of the function change key 281 are disposed to have polarities corresponding to each other, the accuracy of detecting the first state or the second state of the function change key 281 may be improved even under the influence of an external magnetic force.

According to an embodiment, the length (e.g., L1 of FIGS. 10, 11, and 13) of an area in which the function change key 281 is slidable on the key support member 273 may be about 1.2 mm. The X axis in FIGS. 17A to 17C and 18A to 18C represents the position of the function change key 281, which may correspond to 0 in the first state (e.g., see FIG. 10), and 1.2 (unit: mm) in the second state (e.g., see FIG. 11). The position of the function change key 281 between the first state and the second state may correspond to a value between 0 and 1.2. However, the length L1 is not limited, and may be changed, for example, depending on the arrangement of the key cover 271 and the function change key 281. The Y axis in FIGS. 17A to 17C and 18A to 18C may represent magnetic flux values (unit: weber (wb)=1T·m²) measured by the first Hall sensor 283a and the second Hall sensor 283b, as first Hall sensor values and second Hall sensor values.

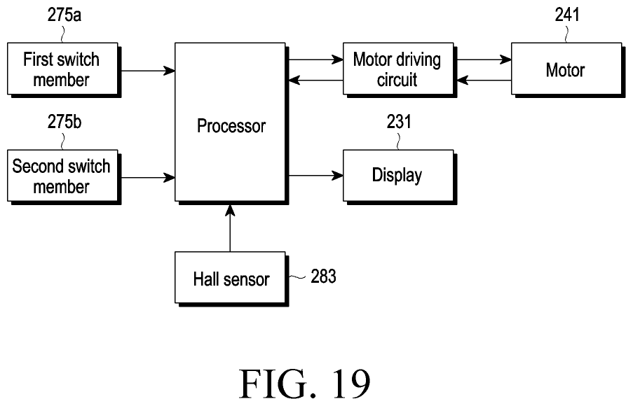

FIG. 19 is a conceptual diagram illustrating an operation of extending or reducing a display by using a key assembly in an electronic device according to an embodiment of the disclosure.

In an embodiment, an electronic device (e.g., the electronic device 101 of FIG. 1 and/or the electronic device 101 of FIGS. 2 to 4, 5A, and 5B) may include at least one key assembly (e.g., the key assembly 207 of FIGS. 6 and 7) disposed in the first housing 201. In an embodiment, the key assembly 207 may include at least one key cover (e.g., the key cover 271 of FIGS. 6, 7, 10, and 11), at least one connecting member (e.g., the connecting member 272 of FIG. 7), a key supporting member (e.g., the key supporting member 273 of FIGS. 6 and 7), a key circuit board (e.g., the key circuit board 274 of FIGS. 6 to 8 and FIGS. 10 to 14), at least one switch member (e.g., the switch member 275 of FIGS. 6 to 8 and FIGS. 10 to 14), a function change key (e.g., the function change key 281 of FIGS. 6 to 11), at least one magnet (e.g., the magnet 282 of FIGS. 6 to 11), at least one Hall sensor (e.g., the Hall sensor 283 of FIGS. 6 and 8 and FIGS. 10 to 14), and/or a magnetic member (e.g., the magnetic member 284 in FIGS. 6 to 8 and FIGS. 10 to 13).

The description given with reference to FIGS. 6 to 15, 16A to 16C, 17A to 17C, and 18A to 18C may be equally applied to the configuration of the key assembly (e.g., the key assembly 207 of FIGS. 6 and 7) in the embodiment of FIG. 19 below, and a redundant description of some contents will be avoided below.

In an embodiment, the key cover 271 may include the first key cover 271a (e.g., the first key cover 271a of FIGS. 7, 10 and 11) and the second key cover 271b (e.g., the second key cover 271b of FIGS. 7, 10 and 11). The first key cover 271a and the second key cover 271b may be disposed respectively at positions corresponding to a plurality of (e.g., two) switch members 275 which individually accommodate an external input (e.g., a click).

In an embodiment, the key support member 273 may be disposed in the accommodation hole 217 (e.g., the accommodation hole 217 of FIG. 7) of the first cover member 211 (e.g., the first cover member 211 of FIG. 7). For example, the key support member 273 may provide an accommodation space for other components of the key assembly 207, together with the accommodation hole 217.

In an embodiment, the key circuit board 274 may be disposed on one surface (e.g., the −X direction surface) of the key support member 273. According to an embodiment, the key circuit board 274 may be electrically connected to the main circuit board (e.g., the first circuit board 248 of FIG. 4) of the electronic device 101. According to an embodiment, at least one switch member 275 and/or at least one Hall sensor 283 may be disposed on one surface (e.g., the −X-direction surface) of the key circuit board 274 facing the key cover 271. According to an embodiment, the key circuit board 274 may transmit data regarding an external input (e.g., a click) detected by the switch member 275 or sliding of the function change key 281 detected by the Hall sensor 283 to the processor (e.g., the processor 120 of FIG. 1) disposed on the first circuit board 248. According to an embodiment, the key circuit board 274 may be formed in a shape that does not overlap the magnetic member 284 sliding together with the function change key 281. Referring to FIGS. 11 and 13, in an embodiment, the key circuit board 274 may not overlap the first magnetic member 284 and the second magnetic member 284 in a direction (e.g., the width direction or X-axis direction of the electronic device 101) intersecting the sliding direction A of the function change key 281.

In an embodiment, the switch member 275 of the key assembly 207 may be provided as a plurality of (e.g., two) switch members 275 that individually receive external inputs (e.g., clicks). According to an embodiment, the switch member 275 may include the first switch member 275a (e.g., the first switch member 275a of FIGS. 6 to 8 and FIGS. 10 and 11) and the second switch member 275b (e.g., the second switch member 275b of FIGS. 6 to 8 and FIGS. 10 and 11) disposed on different areas of the key circuit board 274. For example, the first switch member 275a and the second switch member 275b may be spaced apart from each other in the longitudinal direction (e.g., the Y-axis direction) of the electronic device 101 and electrically connected to the key circuit board 274, respectively. For example, the first switch member 275a may be disposed in a first area of one surface (e.g., the −X-direction surface) of the key circuit board 274. The second switch member 275b may be disposed in a second area of the one surface (e.g., the −X-direction surface) of the circuit board, which does not overlap the first area. For example, the first area and the second area may be disposed to be spaced apart from each other in the longitudinal direction (e.g., the Y-axis direction) of the electronic device 101.

In an embodiment, the function change key 281 of the key assembly 207 may be disposed to be slidable in at least one axial direction (e.g., the direction of the arrow A in FIG. 8) on a portion of the key support member 273. According to an embodiment, the function change key 281 may be disposed on a portion of one surface (e.g., the −X-direction surface) of the key support member 273. For example, the function change key 281 may be disposed between the first switch member 275a and the second switch member 275b and provided to be slidable toward the first switch member 275a or the second switch member 275b. For example, the “sliding direction of the function change key 281” (e.g., FIG. 6 and a second Hall sensor value) may be substantially parallel to the direction (e.g., Y-axis direction) in which the first switch member 275a and the second switch member 275b are spaced from each other, the sliding direction (e.g., the Y-axis direction or the direction of the arrow \textcircled{1} of FIG. 3) of the electronic device 101 (e.g., the electronic device 101 of FIGS. 2 to 4, 5A, and 5B), the longitudinal direction (e.g., the Y-axis direction) of the electronic device 101, and/or the Y-axis direction.

According to an embodiment, the function change key 281 may include the first part 2811 (e.g., the first part 2811 of FIGS. 8 and 9) disposed inside the key assembly 207 and the second part 2812 (e.g., the second part 2812 of FIGS. 8 and 9) protruding from a portion of the first part 2811. For example, the first part 2811 of the function change key 281 may be formed in a form that may be seated in the space between the key cover 271 and the key support member 273. According to an embodiment, the first part 2811 of the function change key 281 has the first end 2811a (e.g., the first end 2811a of FIG. 9) facing the first switch member 275a and the second end 2811b (e.g., the second end 2811b of FIG. 9) facing the second switch member 275b as an end opposite to the first end 2811a. According to an embodiment, at least one magnet 282 may be disposed on one surface (e.g., the −X-direction surface) of the first end 2811a and/or the second end 2811b of the function change key 281.

In an embodiment, the second part 2812 of the function change key 281 may be a protrusion extending from the first part 2811 toward the outside of the electronic device 101. Referring to FIG. 6, according to an embodiment, at least a portion of the second part 2812 of the function change key 281 may protrude to the outside of the electronic device 101 from the space between the first key cover 271a and the second key cover 271b that are spaced apart from each other. For example, the second part 2812 may extend or protrude from a portion of the first part 2811 in a direction (e.g., the −X direction) intersecting the sliding direction (e.g., FIG. 6 and the second Hall sensor value) of the function change key 281. For example, the second part 2812 may be located between the first end 2811a and the second end 2811b of the first part 2811. For example, the extension or protrusion direction (e.g., the −X direction) of the second part 2812 may be substantially perpendicular to the sliding direction (e.g., the −X direction) or to one surface (e.g., the −X-direction surface) of the first part 2811. According to an embodiment, the height (e.g., the height in the X-axis direction) of the end (e.g., the −X-direction surface) of the second part 2812 may be substantially the same as or similar to the height (e.g., the height in the X-axis direction) of the outer surfaces (e.g., the −X-direction surfaces) of the first key cover 271a and the second key cover 271b. For example, the distance (e.g., d2 in FIG. 6) by which the second part 2812 protrudes from the outer surface of the first cover member 211 of the electronic device 101 may be about 0.4 mm to about 0.6 mm, preferably about 0.5 mm.

In an embodiment, the function change key 281 may be provided to be slidable between the first state and the second state. In the disclosure, the “first state” (e.g., see FIGS. 6 and 10) of the function change key 281 may refer to a state in which the first end 2811a of the function change key 281 is located closest or most adjacent to the first switch member 275a. In the disclosure, the “second state” (e.g., see FIGS. 8 and 11 of the function change key 281 may refer to a state in which the second end 2811b of the function change key 281 is located closest to the second switch member 275b. For example, a user may slide the function change key 281 between the first state and the second state by grasping or sliding the second part 2812 of the function change key 281 protruding outward from the electronic device 101, for example, using a finger or a nail, to switch a set function (e.g., volume control or extension or reduction of the display) of the key assembly 207.

According to an embodiment, at least one magnet 282 may be disposed on one end and/or the other end of the function change key 281. For example, the function change key 281 may include a recess or groove in which the magnet 282 may be seated on one surface (e.g., the −X-direction surface) of the one end and/or the other end of the first part 2811.

In an embodiment, the first magnet 282a and the second magnet 282b may include a ferromagnetic substance 284, and may be, for example, permanent magnets. In an embodiment, a portion of the first magnet 282a and/or the second magnet 282b may be an N-pole area, and the other portion may be an S-pole area. In an embodiment, the N-pole area of the first magnet 282a and/or the second magnet 282b may be closer to the at least one Hall sensor 283 (e.g., the first Hall sensor 283a and/or the second Hall sensor 283b) than the S-pole area, or vice versa.

In an embodiment, the first magnet 282a may include the (1-1)^{th} magnet portion 2821a (e.g., the (1-1)^{th} magnet portion 2821a of FIG. 9) and the (1-2)^{th} magnet portion 2822a (e.g., the (1-2)^{th} magnet portion 2822a of FIG. 9) having different polarities. The (1-1)^{th} magnet portion 2821a may be closer to the first Hall sensor 283a than the (1-2)^{th} magnet portion 2822a. According to an embodiment, the (1-1)^{th} magnet portion 2821a and the (1-2)^{th} magnet portion 2822a may be disposed adjacent to each other in a direction (e.g., the Z-axis direction) intersecting the sliding direction A of the function change key 281. In an embodiment, the second magnet 282b may include the (2-1)^{th} magnet portion 2821b (e.g., the (2-1)^{th} magnet portion 2821b of FIG. 9) and the (2-2)^{th} magnet portion 2822b (e.g., the (2-2)^{th} magnet portion 2822b of FIG. 9) having different polarities. The (2-1)^{th} magnet portion 2821b may be closer to the second Hall sensor 283b than the (2-2)^{th} magnet portion 2822b. According to an embodiment, the (2-1)^{th} magnet portion 2821b and the (2-2)^{th} magnet portion 2822b may be disposed adjacent to each other in a direction (e.g., the Z-axis direction) intersecting the sliding direction A of the function change key 281. For example, when the function change key 281 is in the first state, the (1-1)^{th} magnet portion 2821a of the first magnet 282a may be disposed between the (1-2)^{th} magnet portion 2822a and the first Hall sensor 283a, as described below. Similarly, when the function change key 281 is in the second state, the (2-1)^{th} magnet portion 2821b of the second magnet 282b may be disposed between the (2-2)^{th} magnet portion 2822b and the second Hall sensor 283b.

In an embodiment, the (1-1)^{th} magnet portion 2821a and the (1-2)^{th} magnet portion 2821a may have the same polarity. In other words, the first magnet 282a and the second magnet 282b may be disposed such that their poles correspond to each other. For example, the (1-1)^{th} magnet portion 2821a and the (1-2)^{th} magnet portion 2822a of the first magnet 282a may be the N pole and the S pole, respectively, and the (2-1)^{th} magnet portion 2821b and the (2-2)^{th} magnet portion 2822b of the second magnet 282b may be the N pole and the S pole, respectively. Alternatively, the (1-1)^{th} magnet portion 2821a and the (1-2)^{th} magnet portion 2822a of the first magnet 282a may be the S pole and the N pole, respectively, and the (2-1)^{th} magnet portion 2821b and the (2-2)^{th} magnet portion 2822b of the second magnet 282b may be the S pole and the N pole, respectively. When the first magnet 282a and the second magnet 282b are disposed with their poles corresponding to each other, the accuracy of detecting the first state or the second state of the function change key 281 may be improved even under the influence of an external magnetic force, in spite of the influence of the magnetic fields of the external magnets M1, M2, and M3 existing outside the electronic device 101. However, the polarities of the first magnet and the second magnet are not limited to those described above. For example, the first magnet 282a and the second magnet 282b may be disposed with their poles staggered with each other. For example, the (1-1)^{th} magnet portion 2821a and the (1-2)^{th} magnet portion 2822a of the first magnet 282a may be the N pole and the S pole, respectively, and the (2-1)^{th} magnet portion 2821b and the (2-2)^{th} magnet portion 2822b of the second magnet 282b may be the S pole and the N pole, respectively. Alternatively, the (1-1)^{th} magnet portion 2821a and the (1-2)^{th} magnet portion 2822a of the first magnet 282a may be the S pole and the N pole, respectively, and the (2-1)^{th} magnet portion 2821b and the (2-2)^{th} magnet portion 2822b of the second magnet 282b may be the N pole and the S pole, respectively.

In an embodiment, the Hall sensor 283 of the key assembly 207 may include the first Hall sensor 283a and the second Hall sensor 283b disposed on different areas of the key circuit board 274. In an embodiment, the first Hall sensor 283a and the second Hall sensor 283b may provide measurement values of the first Hall sensor 283a and the second Hall sensor 283b regarding the movement or position of the function change key 281 to the processor (e.g., the processor 120 of FIG. 1) electrically connected through the key circuit board 274, respectively. For example, the first Hall sensor 283a and the second Hall sensor 283b may include Hall elements that measure the strengths of magnetic fields, magnetic flux densities, and/or magnetic fluxes or a change in the magnetic fluxes of the first magnet 282a and the second magnet 282b that move together when the function change key 281 slides. In an embodiment, when the function change key 281 is in the first state, the first Hall sensor 283a may face the first magnet 282a, and when the function change key 281 is in the second state, the second Hall sensor 283b may face the second magnet 282b.

In an embodiment, the magnetic member 284 of the key assembly 207 may be disposed on a portion of the key support member 273. For example, the magnetic member 284 may be disposed such that at least a portion of the magnetic member 284 faces at least a portion of a side surface (e.g., a −Z-direction side surface) of the function change key 281. In an embodiment, the magnetic member 284 of the key assembly 207 may be disposed to face the Hall sensors 283 with the function change key 281 interposed therebetween. In an embodiment, the magnetic member 284 may include a material that is magnetized by a magnetic field of the magnet 282 (e.g., the first magnet 282a or the second magnet 282b). For example, the magnetic member 284 may include a magnetic substance, such as iron. In an embodiment, the magnetic member 284 may include the first magnetic end 2841 facing the first magnet 282a, when the function change key 281 is in the first state, the second magnetic end 2842 facing the second magnet 282b when the function change key 281 is in the second state, and the connecting portion 2843 connecting the two ends 2841 and 2842. For example, when the function change key 281 is in the first state, the first magnet 282a may be disposed between the first magnetic end 2841 and the first Hall sensor 283a, and when the function change key 281 is in the second state, the second magnet 282b may be disposed between the second magnetic end 2842 and the second Hall sensor 283b.

In an embodiment, the function change key 281 of the key assembly 207 may include the position indicator 2813 on at least a portion of the first part. According to an embodiment, as the position indicator 2813 is disposed at a position where it may be visible to or concealed from the outside of the electronic device 101 depending on the first state or the second state of the function change key 281, the position indicator 2813 may allow the user to visually recognize the position of the function change key 281 and a set function of the key assembly 207 accordingly. According to an embodiment, the position indicator 2813 may be formed on a portion of a surface (e.g., the −X-direction surface) of the first part 2811 (e.g., the first part 2811 of FIGS. 8 and 9) of the function change key 281, which faces the key covers 271.

Referring to FIG. 19, the processor (e.g., the processor 120 of FIG. 1) of the electronic device 101 may be electrically connected to the first switch member 275a, the second switch member 275b, and the Hall sensor 283 of the key assembly 207, a display, and a motor driving circuit. According to an embodiment, the processor 120 may be disposed on the first circuit board (e.g., the first circuit board 248 of FIG. 4). For example, the first switch member 275a, the second switch member 275b, and the Hall sensor 283 may be electrically connected to the first circuit board 248 through the key circuit board 274.

According to an embodiment, the processor (e.g., the processor 120 of FIG. 1) of the electronic device 101 may receive a measurement value of the first Hall sensor 283a (or a “first Hall sensor value”) and a measurement value of the second Hall sensor 283b (or a “second Hall sensor value”) and determine whether the function change key 281 is in the first state or the second state based on the measurement values. For example, when the first Hall sensor value is greater than a first threshold and the second Hall sensor value is less than the first threshold, the processor 120 may determine that the function change key 281 is in the first state. For example, when the first Hall sensor value is less than the first threshold and the second Hall sensor value is greater than the first threshold, the processor 120 may determine that the function change key 281 is in the second state. For example, the first Hall sensor 283a and the second Hall sensor 283b may be configured to transmit measurement values to the processor periodically, or for example, only when the first Hall sensor value is greater than the first threshold and the second Hall sensor value is less than the first threshold or when the first Hall sensor value is less than the first threshold and the second Hall sensor value is greater than the first threshold.

According to an embodiment, the function change key 281 may switch a set function of the key assembly 207 to correspond to the first state or the second state. In an embodiment, the key assembly 207 may function as a volume control key in the first state and as a display extension or reduction key in the second state, or vice versa. However, the set functions of the key assembly 207 are not limited to what has been described above, and various functions (e.g., activation of a camera module (e.g., the camera modules 249a and 249b of FIG. 3)) may be customized to the key assembly 207.

According to an embodiment, in a specific state (e.g., the first state) of the function change key 281, external inputs (e.g., clicks) applied to the first switch member 275a and the second switch member 275b may correspond to commands for increasing and decreasing a volume, respectively, or vice versa. For example, the processor (e.g., the processor 120 of FIG. 1) may be electrically connected to an audio module (e.g., the audio module 170 of FIG. 1) to control the volume of the audio module. In an embodiment, in the specific state (e.g., the first state) of the function change key 281, when an external input is applied to the first switch member 275a or the second switch member 275b, the volume of the audio module may be increased or decreased by the processor 120.

In an embodiment, in a specific state (e.g., the second state) of the function change key 281, the key assembly 207 may function as the display extension or reduction key. In an embodiment, in the specific state (e.g., the second state) of the function change key 281, external inputs (e.g., clicks) applied to the first switch member 275a and the second switch member 275b may correspond to commands for extending and reducing the display, respectively, or vice versa. For example, when detecting external inputs (e.g., clicks) applied to the first switch member 275a and the second switch member 275b in the specific state (e.g., the second state) of the function change key 281, the processor (e.g., the processor 120 of FIG. 1) may command a driving structure (e.g., the motor module of FIG. 1 and/or the driving structure 240 of FIG. 4) to drive the display to extend or contract. According to an embodiment, the processor 120 may include a motor driver driving circuit electrically connected to a motor (e.g., the motor 241 of FIG. 4) of the driving structure 240. For example, the processor 120 may transmit a pulse width modulation (PWM) signal to the motor 241 to control the speed of the motor 241 and/or the torque of the motor 241 through the motor driver driving circuit. For example, when an external input is applied to the first switch member 275a or the second switch member 275b in a specific state (e.g., the second state) of the function change key 281, the processor 120 may apply a signal (e.g., a PWM signal) to the motor (e.g., the motor 241 of FIG. 4) and a rack gear (e.g., the rack gear 242 of FIG. 4) so that the display may be extended (e.g., FIGS. 3 and 5B) or reduced (e.g., FIGS. 2 and 5A).

An electronic device (e.g., a portable terminal) may include a display having a flat surface or flat and curved surfaces. The electronic device including the display may have limitations in implementing a screen larger than the size of the electronic device due to the structure of the fixed display. Therefore, an electronic device including a rollable display (or a slidable electronic device) is being studied.

For example, an operation of extending or reducing such a rollable display may be implemented by a pair of housings that are slidably connected to each other. For example, a function key or button for inputting the extension or reduction operation of the rollable display may be implemented as a physical key on a sidewall of a housing, for convenience and intuitiveness in use. However, when a function key is added to the housing, it may impair the appearance design of the electronic device and increase a mounting space, which may conflict with the demand for miniaturization of the electronic device. On the contrary, when some of the existing function keys (e.g., volume control keys) are replaced with an additional function key, it may increase the inconvenience of use for users.

According to an embodiment of the disclosure, a key assembly including a function change key disposed to be slidable between a pair of adjacent switch members (e.g., volume control keys) and capable of switching a function (e.g., volume control or display extension or reduction) that may be input to the switch members according to the position of the function change key, and an electronic device including the same may be provided.

The problems to be solved in the disclosure is not limited to the problem mentioned above, and may be extended in various manners within the scope of the spirit and scope of the disclosure.

According to the embodiment of the disclosure, the use of a key assembly in which a key for inputting display extension or reduction is integrated into an existing function key may reduce the number of function keys and a mounting space, thereby contributing to miniaturization of an electronic device and improving an appearance design.

The effects that may be obtained from the disclosure are not limited to the effects mentioned above, and other effects that are not mentioned may be clearly understood by those skilled in the art from the following description.

While the disclosure has been described with respect to an embodiment, by way of example, it should be understood that the embodiment is for illustrative purposes, not limiting the disclosure. It will be obvious to those skilled in the art that various changes may be made in the form and detailed configuration thereof without departing from the overall scope of the disclosure, including the appended claims and their equivalents.

According to an embodiment of the disclosure, the electronic device 101 may include the first housing 201, the second housing 202 configured to slide relative to the first housing, the flexible display 231, and/or the key assembly 207 disposed on a side surface (or a sidewall (e.g., the (1-2)^{th} sidewall 211b and/or the (1-3)^{th} sidewall 211c) of the first housing. The flexible display may include the first display area A1 and the second display area A2 extending from the first display area, and configured to move at least a portion of the second display area based on a slide movement of the second housing. The key assembly may include the key circuit board 274, the first switch member 275a disposed on a first area of the key circuit board, the second switch member 275b disposed on a second area of the key circuit board, the function change key 281, the first magnet 282a, and/or the second magnet 282b. The function change key may be provided to be slidable between the first switch member and the second switch member. The first magnet may be disposed on one end of the function change key and provided to be slidable. The second magnet may be disposed on the other end of the function change key and provided to be slidable. For example, the second area may be spaced apart from the first area.

In an embodiment, the function change key may be provided to be slidable between a first state in which the one end is located closest to the first switch member and a second state in which the other end is located closest to the second switch member.

In an embodiment, the key assembly may further include the first Hall sensor 283a and the second Hall sensor 283b disposed in an area between the first area and the second area on the key circuit board. The first Hall sensor may be closer to the first magnet than the second Hall sensor, and the second Hall sensor may be closer to the second magnet than the first Hall sensor.

In an embodiment, when the function change key is in the first state, the first Hall sensor may at least partially face the first magnet. When the function change key is in the second state, the second Hall sensor may at least partially face the second magnet.

In an embodiment, the electronic device (e.g., the processor 120 of FIG. 1) may be configured to detect a position of the function change key based on a magnetic flux value of the first magnet measured by the first Hall sensor and a magnetic flux value of the second magnet measured by the second Hall sensor.

In an embodiment, the first magnet may include the (1-1)^{th} magnet portion 2821a and the (1-2)^{th} magnet portion 2822a having different polarities, and the (1-1)^{th} magnet portion is closer to the first Hall sensor than the (1-2)^{th} magnet portion. The second magnet may include the (2-1)^{th} magnet portion 2821b and the (2-2)^{th} magnet portion 2822b having different polarities, the (2-1)^{th} magnet portion may be closer to the second Hall sensor than the (2-2)^{th} magnet portion, and the (1-1)^{th} magnet portion and the (2-2)^{th} magnet portion may have the same polarity.

In an embodiment, the electronic device (e.g., the processor 120 of FIG. 1) may be configured to perform a set function based on an external input detected by at least one of the first switch member or the second switch member. The set function may be different when the function change key is in the first state and the second state.

In an embodiment, at least one of the set functions may be set to extend or reduce the second display area by sliding the second housing relative to the first housing in response to the external input detected by the first switch member or the second switch member.

In an embodiment, the function change key may include a first part facing the first housing, and a second part protruding from a portion of the first part toward an outside of the electronic device.

In an embodiment, the key assembly may include the first key cover 271a and the second key cover 271b forming a portion of an exterior of the electronic device. The first key cover and the second key cover may be spaced apart from each other in a direction of the slide movement, the first key cover is disposed at positions corresponding to the first switch member and the first key cover is disposed at positions corresponding to the second switch member.

In an embodiment, at least a portion of the first part and the second part may be exposed to the outside of the electronic device through a gap between the first key cover and the second key cover. The second part may be displaced by a predetermined distance between the first key cover and the second key cover during the slide movement.

In an embodiment, the first part may include the position indicator 2813 on at least a portion of the first part. The position indicator may be configured to be exposed to the outside of the electronic device through the gap between the first key cover and the second key cover or configured to be concealed by the first key cover or the second key cover, when the function change key is in the first state or the second state.

In an embodiment, the key assembly may further include the magnetic member 284. The magnetic member may include the first magnetic end 2841 disposed adjacent to the first magnet to be magnetized by the first magnet, when the function change key is in the first state. The magnetic member may include the second magnetic end 2842 disposed adjacent to the second magnet to be magnetized by the second magnet, when the function change key is in the second state.

In an embodiment, when the function change key is in the first state, the first magnetic end may at least partially face the first magnet. When the function change key is in the second state, the second magnetic end may at least partially face the second magnet.

In an embodiment, when viewed from above, the key circuit board may not overlap the first magnet and the second magnet.

In an embodiment, the key assembly may further include the key support member 271. The key support member may include one surface on which the function change key and the key circuit board are disposed, and the other surface opposite to the one surface, which faces the first housing.

According to an embodiment of the disclosure, the electronic device 101 may include the first housing 201, the second housing 202 configured to slide relative to the first housing, the flexible display 231, and the key assembly 207 disposed on a side surface of the first housing. The flexible display may include the first display area A1 and the second display area A2 extending from the first display area. The flexible display may be configured to move at least a portion of the second display area based on a slide movement of the second housing. The key assembly may include the key circuit board 274, the first switch member 275a disposed on a first area of the key circuit board, the second switch member 275b disposed on a second area of the key circuit board, and/or the function change key 281. The function change key may be disposed between the first switch member and the second switch member, and provided to be slidable between a first position (or a first state) closest to the first switch member and a second position (or a second state) closest to the second switch member. The electronic device (e.g., the processor 120 of FIG. 1) may be configured to perform a set function based on an external input detected by at least one of the first switch member or the second switch member, and perform different functions, when the function change key is in the first state and the second state.

In an embodiment, the key assembly may include the first magnet 282a disposed on one end of the function change key so as to face the first switch member, and slidable. The key assembly may include the second magnet 282b disposed on the other end of the function change key so as to face the second switch member, and slidable.

In an embodiment, the key assembly may include the first Hall sensor 283a and the second Hall sensor (283b disposed in an area between the first area and the second area on the key circuit board. The first Hall sensor may be closer to the first magnet than the second Hall sensor. The second Hall sensor may be closer to the second magnet than the first Hall sensor.

In an embodiment, the electronic device (e.g., the processor 120 of FIG. 1) may be configured to detect a position of the function change key based on a magnetic flux value of the first magnet measured by the first Hall sensor and a magnetic flux value of the second magnet measured by the second Hall sensor.

In an embodiment, at least one of the set functions may be set to extend or reduce the second display area by sliding the second housing relative to the first housing in response to the external input detected by the first switch member or the second switch member.

The electronic device according to an embodiment of the disclosure may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that an embodiment of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases. As used herein, such terms as “1^{st}” and “2^{nd}”, or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wiredly), wirelessly, or via a third element.

As used in connection with an embodiment of the disclosure, the term “module” may include a unit implemented in hardware, software, or firmware, and may interchangeably be used with other terms, for example, logic, logic block, part, or circuitry. A module may be a single integral component, or a minimum unit or part thereof, adapted to perform one or more functions. For example, according to an embodiment, the module may be implemented in a form of an application-specific integrated circuit (ASIC).

An embodiment as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to an embodiment of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to an embodiment, each component (e.g., a module or a program) of the above-described components may include a single entity or multiple entities, and some of the multiple entities may be separately disposed in different components. According to an embodiment, one or more of the above-described components may be omitted, or one or more other components may be added. Alternatively or additionally, a plurality of components (e.g., modules or programs) may be integrated into a single component. In such a case, the integrated component may still perform one or more functions of each of the plurality of components in the same or similar manner as they are performed by a corresponding one of the plurality of components before the integration. According to an embodiment, operations performed by the module, the program, or another component may be carried out sequentially, in parallel, repeatedly, or heuristically, or one or more of the operations may be executed in a different order or omitted, or one or more other operations may be added.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a first housing;
a second housing configured to slide relative to the first housing;
a flexible display including a first display area and a second display area extending from the first display area, and configured to move at least a portion of the second display area based on a slide movement of the second housing; and
a key assembly disposed on a side surface of the first housing,
wherein the key assembly includes:
a key circuit board,
a first switch member disposed on a first area of the key circuit board,
a second switch member disposed on a second area of the key circuit board,
a function change key disposed to be slidable between the first switch member and the second switch member,
a first magnet disposed on one end of the function change key to be slidable, and
a second magnet disposed on the other end of the function change key to be slidable.

2. The electronic device of claim 1, wherein the function change key is slidable between a first state in which the one end is located closest to the first switch member and a second state in which the other end is located closest to the second switch member.

3. The electronic device of claim 2,
wherein the key assembly further includes a first Hall sensor and a second Hall sensor disposed in an area between the first area and the second area on the key circuit board,
wherein the first Hall sensor is closer to the first magnet than the second Hall sensor, and
wherein the second Hall sensor is closer to the second magnet than the first Hall sensor.

4. The electronic device of claim 3,
wherein when the function change key is in the first state, the first Hall sensor at least partially faces the first magnet, and
wherein when the function change key is in the second state, the second Hall sensor at least partially faces the second magnet.

5. The electronic device of claim 3, wherein the electronic device is configured to detect a position of the function change key based on a magnetic flux value of the first magnet measured by the first Hall sensor and a magnetic flux value of the second magnet measured by the second Hall sensor.

6. The electronic device of claim 3,
wherein the first magnet includes a (1-1)^{th} magnet portion and a (1-2)^{th} magnet portion having different polarities,
wherein the (1-1)^{th} magnet portion is closer to the first Hall sensor than the (1-2)^{th} magnet portion,
wherein the second magnet includes a (2-1)^{th} magnet portion and a (2-2)^{th} magnet portion having different polarities, the (2-1)^{th} magnet portion is closer to the second Hall sensor than the (2-2)^{th} magnet portion, and
wherein the (1-1)^{th} magnet portion and the (2-2)^{th} magnet portion have the same polarity.

7. The electronic device of claim 2,
wherein the electronic device is configured to perform a set function based on an external input detected by at least one of the first switch member or the second switch member, and
wherein the set function is different when the function change key is in the first state and the second state.

8. The electronic device of claim 7, wherein the set function is set to extend or reduce the second display area by sliding the second housing relative to the first housing in response to the external input detected by the first switch member or the second switch member.

9. The electronic device of claim 2, wherein the function change key includes:
a first part facing the first housing; and
a second part protruding from a portion of the first part toward an outside of the electronic device.

10. The electronic device of claim 9,
wherein the key assembly includes a first key cover and a second key cover forming a portion of an exterior of the electronic device,
wherein the first key cover and the second key cover are spaced apart from each other in a direction of the slide movement, and
wherein the first key cover is disposed at positions corresponding to the first switch member and the first key cover is disposed at positions corresponding to the second switch member.

11. The electronic device of claim 10,
wherein at least a portion of the first part and the second part are exposed to the outside of the electronic device through a gap between the first key cover and the second key cover, and
wherein the second part is displaced by a predetermined distance between the first key cover and the second key cover during the slide movement.

12. The electronic device of claim 11,
wherein the first part includes a position indicator on at least a of the first part, and
wherein the position indicator is configured to be exposed to the outside of the electronic device through the gap between the first key cover and the second key cover or configured to be concealed by the first key cover or the second key cover, when the function change key is in the first state or the second state.

13. The electronic device of claim 2,
wherein the key assembly further includes a magnetic member, and
wherein the magnetic member includes:
a first magnetic end disposed adjacent to the first magnet to be magnetized by the first magnet, when the function change key is in the first state; and
a second magnetic end disposed adjacent to the second magnet to be magnetized by the second magnet, when the function change key is in the second state.

14. The electronic device of claim 13,
wherein when the function change key is in the first state, the first magnetic end at least partially faces the first magnet, and
wherein when the function change key is in the second state, the second magnetic end at least partially faces the second magnet.

15. The electronic device of claim 2, when viewed from above, the key circuit board does not overlap the first magnet and the second magnet.

16. An electronic device comprising:
a first housing;
a second housing configured to slide relative to the first housing;
a flexible display including a first display area and a second display area extending from the first display area, and configured to move at least a portion of the second display area based on a slide movement of the second housing; and
a key assembly disposed on a side surface of the first housing,
wherein the key assembly includes:
a key circuit board;
a first switch member disposed on a first area of the key circuit board;
a second switch member disposed on a second area of the key circuit board; and
a function change key disposed to be slidable between the first switch member and the second switch member,
wherein the function change key is configured to be slidable between a first position adjacent to the first switch member and a second position adjacent to the second switch member, and
wherein the electronic device is configured to:
perform a set function based on an external input detected by at least one of the first switch member or the second switch member, and
perform different functions, when the function change key is in the first position and the second position.

17. The electronic device of claim 16,
wherein the key assembly includes:
a first magnet disposed on one end of the function change key so as to face the first switch member and to be slidable, and
a second magnet disposed on the other end of the function change key to so as to face the second switch member and to be slidable.

18. The electronic device of claim 17, wherein the key assembly further includes a first Hall sensor and a second Hall sensor disposed in an area between the first area and the second area on the key circuit board,
wherein the first Hall sensor is closer to the first magnet than the second Hall sensor, and
wherein the second Hall sensor is closer to the second magnet than the first Hall sensor.

19. The electronic device of claim 18, wherein the electronic device is configured to detect a position of the function change key based on a magnetic flux value of the first magnet measured by the first Hall sensor and a magnetic flux value of the second magnet measured by the second Hall sensor.

20. The electronic device of claim 16, wherein the set function is set to extend or reduce the second display area by sliding the second housing relative to the first housing in response to the external input detected by the first switch member or the second switch member.
